(19) United States
(12) Patent Application Publication
(10) Pub. No.: US 2023/0288492 A1
(43) Pub. Date: Sep. 14, 2023

(54) ADJUSTMENT POWER MEASURING DEVICE, ADJUSTMENT POWER MEASURING SYSTEM, ADJUSTMENT POWER MEASURING METHOD, AND PROGRAM

(71) Applicant: MITSUBISHI HEAVY INDUSTRIES, LTD., Tokyo (JP)

(72) Inventors: Takaharu Hiroe, Tokyo (JP); Kazunari Ide, Tokyo (JP); Ryo Sase, Tokyo (JP)

(73) Assignee: MITSUBISHI HEAVY INDUSTRIES, LTD., Tokyo (JP)

(21) Appl. No.: 18/016,386

(22) PCT Filed: Nov. 12, 2021
(86) PCT No.: PCT/JP2021/041661

§ 371 Date: Jan. 16, 2023

(30) Foreign Application Priority Data
Nov. 16, 2020 (JP) 2020-190376

(51) Int. Cl. G01R 31/40; H02J 13/00

(52) U.S. Cl. CPC G01R 31/40; H02J 13/00002

(57) ABSTRACT

An adjustment power measuring device includes: an acquisition unit for acquiring effective power exchanged at a connection point with an adjustment power providing means capable of providing adjustment power to a first transmission and distribution network; a first calculation unit for calculating a power demand or a power supply for an entire electric power system including the first transmission and distribution network; and a measuring unit for measuring first adjustment power provided to the first transmission and distribution network by the adjustment power providing means on the basis of the effective power and the power demand or the power supply of the electric power system.

### TECHNICAL FIELD

The present disclosure relates to an adjustment power measuring device, an adjustment power measuring system, an adjustment power measuring method, and a program.

The present application claims priority based on Japanese Patent Application No. 2020-190376 filed in Japan on Nov. 16, 2020, the contents of which are incorporated herein by reference.

### BACKGROUND ART

The electric power system combines adjustment power of a generator by (1) governor-free (GF), (2) load frequency control (LFC), and (3) economic load distribution control (EDC) according to a variation cycle of electric power demand, and a frequency is maintained. With the deregulation of electric power, a system operator is supplied with the adjustment power from a power generation company in the public offering or in the market. Electric power demand varies from moment to moment. When the electric power demand of a power transmission and distribution system exceeds the electric power supply, a frequency of the power transmission and distribution system falls below a reference value, and conversely, when the electric power supply exceeds the electric power demand, the frequency rises above the reference value. The adjustment power is for balancing the supply and demand that varies from moment to moment, and when the adjustment power works ideally, the frequency matches the reference value.

The adjustment power is increased or decreased based on the variation in the frequency of the system. When the frequency of the system is insufficient to the reference value, the system operator is supplied with positive adjustment power from the power generation company. On the contrary, when the frequency exceeds the reference value, negative adjustment power is supplied from the power generation company. The adjustment power supplement is actually carried out by the power generation company adjusting the output of a supplier and responding to a command from the system operator from moment to moment.

The stable supply of the electric power depends on the power generation company providing the adjustment power as commanded. Therefore, it is important for the power generation company to provide the adjustment power as commanded, and when it is not possible to do so, it is considered to settle the payment according to the performance of the provision.

However, in a case where the system operator commands the adjustment power that is more than necessary in an extremely short time, the power generation company cannot comply with the command and is subject to a settlement fee as a penalty. Further, since the frequencies are different for each location in the electric power system (for example, in Japan, frequencies in Hokkaido and Kyushu oscillate in opposite phases with a cycle of 3 to 5 seconds), it is desirable for the system operator to command the adjustment power finely for each supplier’s location, but it is unrealistic to command the adjustment power for the oscillation at a cycle of 3 to 5 seconds, thereby the supplier is left to the governor free in which the adjustment power is autonomously performed. Since the governor-free adjustment power is autonomously performed by each supplier regardless of the command, the adjustment power that is generated in a short cycle by the supplier is not measured, no settlement is made, and the power generation company cannot receive compensation.

The technology of autonomously measuring the adjustment power using measurable values such as frequencies or electric power greatly contributes to the efficiency and transparency of the electric power systems rather than measuring the adjustment power by relying on anthropogenic factors such as commands of the system operator. For example, PTL 1 discloses a method of counting a component, which depends on the frequency of the location of the supplier among outputs of the supplier, as the adjustment power.

### CITATION LIST

### Patent Literature

[PTL 1] Japanese Patent No. 6664016

### SUMMARY OF INVENTION

### Technical Problem

The related art as in PTL 1 uses the fact that variation in electric power supply and demand appears as variation in frequencies. For example, today, communication technology has made it possible to remotely know the electric power supply and demand of consumers or suppliers connected to the electric power system, but it is difficult to measure in real time the components of the electric power demand that is changed rapidly with cycles of one second or less. Therefore, it is rational to regard the variation in the frequency of the connection point between the consumer or the supplier and the electric power system as the variation in the supply and demand.

However, in the related art, when a value of the variation in the frequency is small, the adjustment power tends to be underestimated. For example, an error is likely to occur on the underestimation side for a gradual variation in several hours, such as a daily variation of electric power demand. In the related art, when the value of the variation in the frequency approaches zero, an adjustment power coefficient indicating an influence degree of the effective electric power, which is supplied by the supplier, with respect to the variation in the frequency also becomes zero, thereby there is a possibility that the adjustment power cannot be calculated correctly. Therefore, there has been a demand for technology capable of appropriately measuring long-cycle and sustainable adjustment power, such as daily electric power demand variation.

The present disclosure has been made in view of such problems and provides an adjustment power measuring device, an adjustment power measuring system, an adjustment power measuring method, and a program capable of accurately measuring long-cycle and sustainable adjustment power. Solution to Problem

According to one aspect of the present disclosure, an adjustment power measuring device (10, 50) is an adjustment power measuring device (10, 50) that measures adjustment power of an electric power supply and demand balance provided to a first power transmission and distribution network that is a management target among a plurality of power transmission and distribution networks included in an electric power system, the adjustment power measuring device (10, 50) includes: an acquisition unit (1001, 5001, 5003) that acquires effective electric power exchanged at a connection point with adjustment power providing means capable of providing adjustment power to the first power transmission and distribution network; a first calculation unit (1002, 5004) that calculates electric power demand or electric power supply of an entire electric power system including the first power transmission and distribution network; and a measuring unit (1004, 5005) that measures first adjustment power provided to the first power transmission and distribution network by the adjustment power providing means, based on the effective electric power and the electric power demand or the electric power supply of the electric power system.

According to another aspect of the present disclosure, an adjustment power measuring system (1) is an adjustment power measuring system (1) that measures adjustment power of an electric power supply and demand balance provided to a first power transmission and distribution network that is a management target among a plurality of power transmission and distribution networks included in an electric power system, the adjustment power measuring system (1) includes: an acquisition unit (1001, 5001, 5003) that acquires effective electric power exchanged at a connection point with adjustment power providing means capable of providing adjustment power to the first power transmission and distribution network; a first calculation unit (1002, 5004) that calculates electric power demand or electric power supply of an entire electric power system including the first power transmission and distribution network; and a measuring unit (1004, 5005) that measures first adjustment power provided to the first power transmission and distribution network by the adjustment power providing means, based on the effective electric power and the electric power demand or the electric power supply of the electric power system.

According to still another aspect of the present disclosure, an adjustment power measuring method is an adjustment power measuring method of measuring adjustment power of an electric power supply and demand balance provided to a first power transmission and distribution network that is a management target among a plurality of power transmission and distribution networks included in an electric power system, the adjustment power measuring method includes: a step of acquiring effective electric power exchanged at a connection point with adjustment power providing means capable of providing adjustment power to the first power transmission and distribution network; a step of calculating electric power demand or electric power supply of an entire electric power system including the first power transmission and distribution network; and a step of measuring first adjustment power provided to the first power transmission and distribution network by the adjustment power providing means, based on the effective electric power and the electric power demand or the electric power supply of the electric power system.

According to still another aspect of the present disclosure, a program causes a computer of an adjustment power measuring device (10, 50) that measures adjustment power of an electric power supply and demand balance provided to a first power transmission and distribution network that is a management target among a plurality of power transmission and distribution networks included in an electric power system, to execute: a step of acquiring effective electric power exchanged at a connection point with adjustment power providing means capable of providing adjustment power to the first power transmission and distribution network; a step of calculating electric power demand or electric power supply of an entire electric power system including the first power transmission and distribution network; and a step of measuring first adjustment power provided to the first power transmission and distribution network by the adjustment power providing means, based on the effective electric power and the electric power demand or the electric power supply of the electric power system.

### Advantageous Effects of Invention

According to an adjustment power measuring device, an adjustment power measuring system, an adjustment power measuring method, and a program of the present disclosure, it is possible to accurately measure adjustment power for compensating for long-cycle supply and demand variation in electric power.

### BRIEF DESCRIPTION OF DRAWINGS

FIG. 1 is a diagram illustrating an overall configuration of an adjustment power measuring system according to a first embodiment of the present disclosure.

FIG. 2 is a diagram illustrating a configuration of the adjustment power measuring system according to the first embodiment of the present disclosure in detail.

FIG. 3 is a block diagram illustrating a hardware configuration of a server and measurement equipment according to the first embodiment of the present disclosure.

FIG. 4 is a block diagram illustrating a functional configuration of the measurement equipment according to the first embodiment of the present disclosure.

FIG. 5 is a block diagram illustrating a functional configuration of the server according to the first embodiment of the present disclosure.

FIG. 6 is a block diagram illustrating a functional configuration of a server according to a second embodiment of the present disclosure.

FIG. 7 is a block diagram illustrating a functional configuration of a server according to a third embodiment of the present disclosure.

FIG. 8 is a block diagram illustrating a functional configuration of measurement equipment according to a fourth embodiment of the present disclosure.

FIG. 9 is a block diagram illustrating a functional configuration of a server according to the fourth embodiment of the present disclosure.

FIG. 10 is a block diagram illustrating a functional configuration of measurement equipment according to a fifth embodiment of the present disclosure.

FIG. 11 is a block diagram illustrating a functional configuration of measurement equipment according to a sixth embodiment of the present disclosure.

FIG. 12 is a block diagram illustrating a functional configuration of measurement equipment according to a seventh embodiment of the present disclosure.

FIG. 13 is a block diagram illustrating a functional configuration of measurement equipment and a virtualization server according to an eighth embodiment of the present disclosure.

FIG. 14 is a block diagram illustrating a functional configuration of measurement equipment and a virtualization server according to a ninth embodiment of the present disclosure.

FIG. 15 is a block diagram illustrating a functional configuration of measurement equipment according to a tenth embodiment of the present disclosure.

### DESCRIPTION OF EMBODIMENTS

### First Embodiment

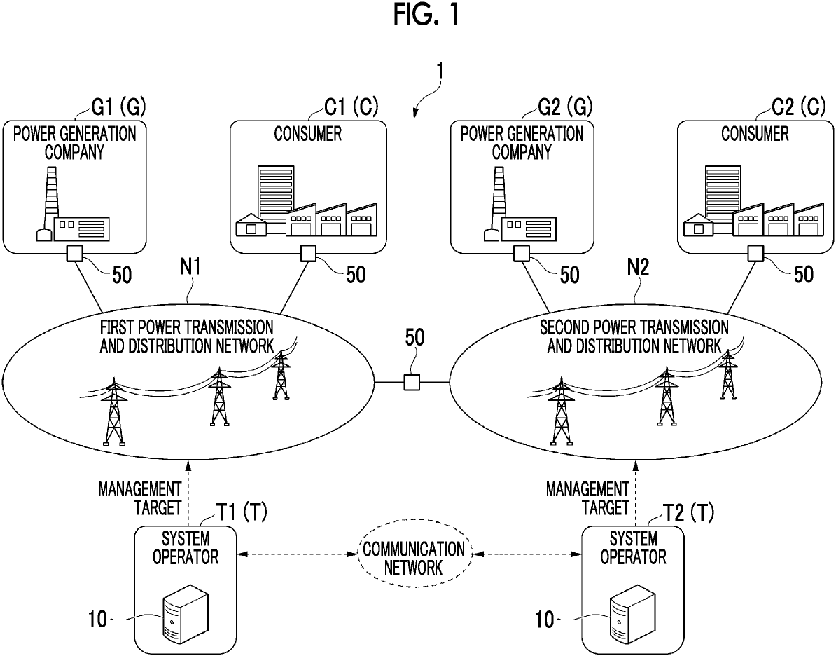

Hereinafter, an adjustment power measuring system 1 according to a first embodiment of the present disclosure will be described with reference to FIGS. 1 to 5.

### (Overall Configuration of Adjustment Power Measuring System)

FIG. 1 is a diagram illustrating an overall configuration of the adjustment power measuring system according to the first embodiment of the present disclosure.

FIG. 1 illustrates an example of an electric power system. The electric power system has power transmission and distribution networks N (a first power transmission and distribution network N1, a second power transmission and distribution network N2) managed by each of a plurality of system operators T (T1, T2). A power generation company G (G1, G2) that generates electric power and supplies the electric power to the power transmission and distribution network N and a consumer C (C1, C2) who consumes the electric power, which is transmitted and distributed via the power transmission and distribution network N, are connected to each power transmission and distribution network N. The first power transmission and distribution network N1 and the second power transmission and distribution network N2 are connected to each other, and it is possible to transmit and receive electric power by a contract between the system operators T1 and T2.

FIG. 1 illustrates an example in which the electric power system has only two power transmission and distribution networks N for the sake of simplification of description, but the present disclosure is not limited thereto. In another embodiment, the electric power system has three or more power transmission and distribution networks N, and there may be three or more system operators T who manage each power transmission and distribution network N. A plurality of power generation companies G and a plurality of consumers C may be connected to each power transmission and distribution network N.

As illustrated in FIG. 1, the adjustment power measuring system 1 includes a server 10 and measurement equipment 50.

The measurement equipment 50 is, for example, an electric power meter. The measurement equipment 50 is installed at a connection point between the power transmission and distribution network N and adjustment power providing means managed by the power generation company G or the like, and measures the effective electric power exchanged at the connection point. The “adjustment power providing means” is a device or the like capable of providing adjustment power of an electric power supply and demand balance with respect to the power transmission and distribution network N to which the power generation company G or the like is connected. Specifically, taking the first power transmission and distribution network N1 as an example, it refers to a power source (described later) managed by the power generation company G1, a stabilization machine, a load managed by the consumer C1, and the second power transmission and distribution network N2 managed by another system operator T2.

The server 10 is managed (or operated) by the system operator T. In the present embodiment, the server 10 functions as the “adjustment power measuring device” that measures the adjustment power of the adjustment power providing means connected to the power transmission and distribution network N managed by each system operator T.

### (Details of Configuration of Adjustment Power Measuring System)

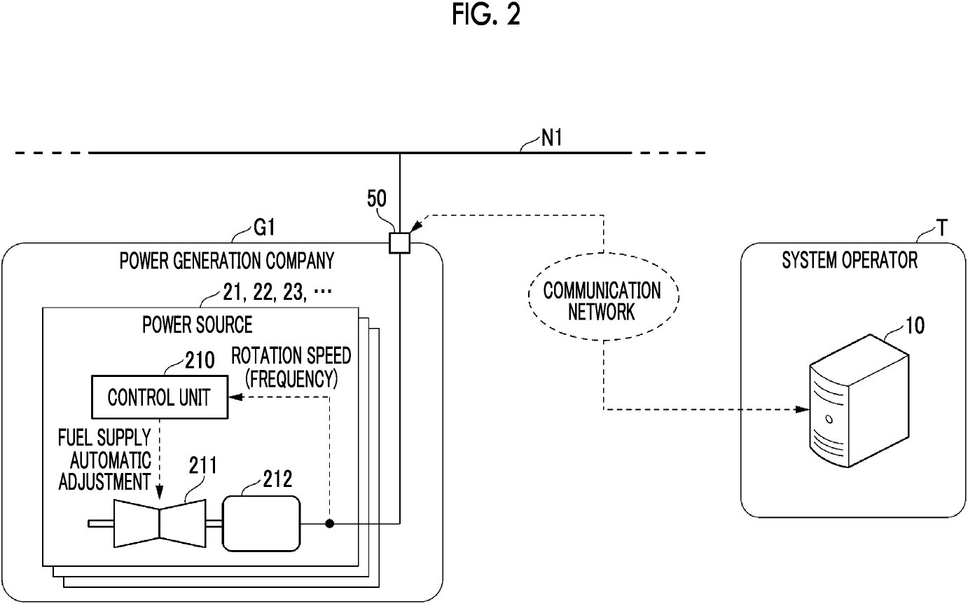

FIG. 2 is a diagram illustrating a configuration of the adjustment power measuring system according to the first embodiment of the present disclosure in detail.

FIG. 2 illustrates an example of the power generation company G1. As illustrated in FIG. 2, the power generation company G1 manages a plurality of power sources 21, 22, 23, ... Although not illustrated, the power generation company G2 also manages a plurality of power sources 21, 22, 23, ...

Hereinafter, one power source 21 among the plurality of power sources 21, 22, 23, .. of the power generation company G1 will be described as an example. The configurations and functions of the other power sources 22, 23, . . are the same as those of the power source 21.

The power source 21 includes a control unit 210, a turbine device 211 (for example, a gas turbine, a steam turbine, or the like), and a generator 212.

The control unit 210 performs operation control of the turbine device 211 and the generator 212. Particularly, the control unit 210 constantly monitors a rotation speed (corresponding to an output frequency) of the generator 212 and automatically adjusts the amount of fuel or steam supplied to the turbine device 211 (governor-free operation) such that the rotation speed is kept constant. According to such operation control, for example, in a case where a load (electric power demand) is increased in a short period of time and a rotation speed of the generator 212 is decreased, the control unit 210 immediately increases the amount of fuel or the like supplied to the turbine device 211 to compensate for the decrease in the rotation speed. The increase in an output when the generator 212 returns to the original rotation speed is the “adjustment power” provided by the power source 21 in response to the increase in the above described load (the electric power demand). As described above, the adjustment power is sequentially provided by the governor-free operation of the power source 21 with respect to short-cycle (cycle of substantially 3 to 5 seconds) electric power demand variation.

The power source 21 is connected to the first power transmission and distribution network N1. The measurement equipment 50 is installed at the connection point between the power source 21 and the first power transmission and distribution network N1. The measurement equipment 50 acquires a measured value of the effective electric power output from the power source 21 to the first power transmission and distribution network N1 (hereinafter, also referred to as the “effective electric power measured value P”). The measurement equipment 50 transmits an effective electric power measured value P, which is output by the power source 21, to the server 10 of the system operator T1 who manages the first power transmission and distribution network N1 to which the power source 21 is connected via a predetermined communication network (Internet line or the like). Similarly, the measurement equipment 50, which is installed at the connection point between the other power sources 22, 23, .. and the first power transmission and distribution network N1, acquires the effective electric power measured value P, which is output from each of the power sources 22, 23, . . to the first power transmission and distribution network N1, and transmits the acquired effective electric power measured value P to the server 10.

### (Hardware Configuration of Server)

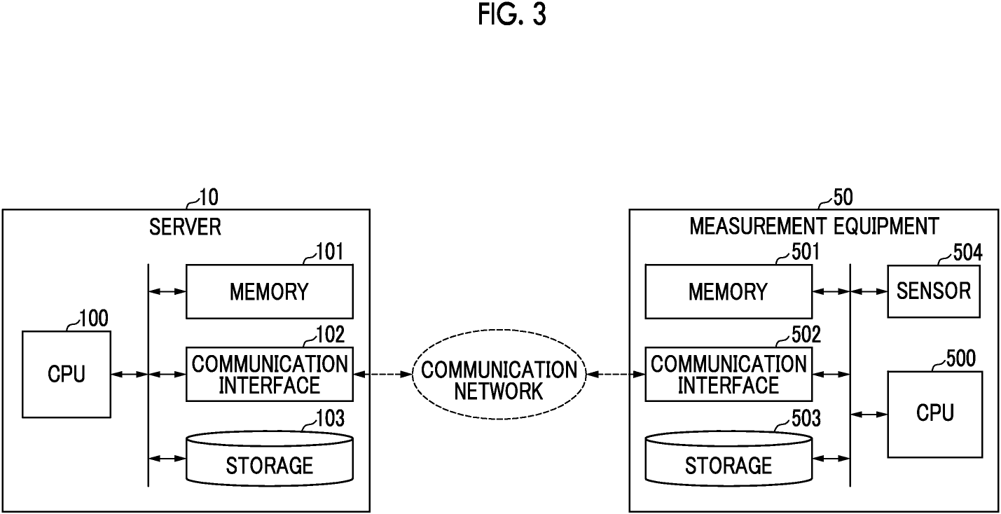

FIG. 3 is a block diagram illustrating a hardware configuration of a server and measurement equipment according to the first embodiment of the present disclosure.

As illustrated in FIG. 3, the server 10 includes a CPU 100, a memory 101, a communication interface 102, and a storage 103.

The CPU 100 is a processor that controls the entire operation of the server 10.

The memory 101 is a so-called main storage device, and instructions and data for the CPU 100 to operate based on a program are loaded.

The communication interface 102 is an interface machine for exchanging information with an external device. The external device is the measurement equipment 50 and the server 10 managed by another system operator T. In the present embodiment, the communication means and the communication method implemented by the communication interface 102 are not particularly limited. For example, the communication interface 102 may be a wired connection interface for implementing wired communication or may be a wireless communication module for implementing wireless communication.

The storage 103 is a so-called auxiliary storage device and may be, for example, a hard disk drive (HDD), a solid state drive (SSD), or the like.

### (Hardware Configuration of Measurement Equipment)

As illustrated in FIG. 3, the measurement equipment 50 includes a CPU 500, a memory 501, a communication interface 502, a storage 503, and a sensor 504.

The CPU 500 is a processor that controls the entire operation of the measurement equipment 50.

The memory 501 is a so-called main storage device, and instructions and data for the CPU 500 to operate based on a program are loaded.

The communication interface 502 is an interface machine for exchanging information with an external device. The external device is a server 10 managed by the system operator T who manages the power transmission and distribution network N to which the measurement equipment 50 is connected. The communication means and the communication method implemented by the communication interface 502 are the same as those of the communication interface 102 of the server 10.

The storage 503 is a so-called auxiliary storage device and may be, for example, a hard disk drive (HDD), a solid state drive (SSD), or the like.

The sensor 504 is a measuring means for measuring the effective electric power exchanged at the connection point between the adjustment power providing means and the power transmission and distribution network N. For example, the sensor 504 acquires the measured value (hereinafter, it is also described as the “effective electric power measured value P₁”) of the effective electric power transmitted from the power source 21 of the power generation company G1 to the first power transmission and distribution network N1 at a constant cycle (for example, 100 ms cycle).

### (Regarding Measuring Method of Adjustment Power in Related Art)

A measuring method of adjustment power in the related art will be described. In the governor-free operation performed by the control unit of the power source, an output (that is, the adjustment power ΔP), which is additionally generated by the power source in accordance with the variation amount (the frequency deviation Δf) in the rotation speed of the generator, is defined as Equation (1) by using a speed adjustment rate δ.

$$\text{Δ} P = - \frac{1}{δ} {P}_{n} \frac{\text{Δ} f}{{f}_{n}} \qquad \text{(1)}$$

In Equation (1), “fₙ” is a reference frequency [Hz] (for example, 50 Hz or the like) of the electric power system, and “Pₙ” is a rated output [MW] of the supplier. “Δf” is obtained by subtracting an actual frequency from the reference frequency and becomes a negative value when the actual frequency exceeds the reference frequency. This relational expression is nominal to indicate the static equilibrium state of the frequency and the output, and actually, there is an error due to the time delay of the output of the power source. The main delays are the inertia of the power source or the operation delay of the control unit.

For example, the adjustment power measuring device in the related art as described in PTL 1 is for measuring a true value of the adjustment power ΔP of the power generation company even when there is such an output time delay. In the related art, the adjustment power measuring device acquires the effective electric power measured value P, which is output by the power source to the power transmission and distribution network by the measurement equipment installed at the connection point between the power source and the power transmission and distribution network, and the frequency measured value f. When the variation in the effective electric power supplied by the power source to the power transmission and distribution network is set as “ΔP” and the frequency deviation of the connection point between the power source and the power transmission and distribution network is set to “Δf”, the adjustment power measuring device calculates an adjustment power coefficient “kₚ” of the power source by using following Equation (2). Following equation (2) is for counting as the adjustment power the contribution to canceling the same frequency deviation out of the variation in the same effective electric power, and the unit of the adjustment power coefficient is [W/Hz].

$${k}_{p} = \frac{{\sum }_{t} \text{Δ} P \left(t\right) ⋅ \text{Δ} f \left(t\right)}{{\sum }_{t} \text{Δ} f {\left(t\right)}^{2}} \qquad \text{(2)}$$

In the adjustment power measuring device, the adjustment power ΔP_{R} of the power source is calculated by using following Equation (3) using the adjustment power coefficient kp.

$$\text{Δ} {P}_{\text{R}} \left(t\right) = - {k}_{p} \left|\text{Δ} f \left(t\right)\right| \qquad \text{(3)}$$

A value obtained by integrating the above result for a certain period of time, such as 24 hours, 1 hour, or 30 minutes, is defined as the adjustment electric power amount generated by the power source. Equation (4) represents the adjustment electric power amount from time tᵢₙᵢ to time tₜₑᵣ.

$${W}_{\left[{t}_{i n i} , {t}_{t e r}\right]} = {\sum }_{t = {t}_{i n i ,} {t}_{i n i} + \text{Δ} t , ⋯ , {t}_{t e r}} \text{Δ} {P}_{\text{R}} \left(t\right) ⋅ \text{Δ} t \qquad \text{(4)}$$

The variation in the effective electric power ΔP(t) may be a deviation of the effective electric power P(t) from an expected value E [ · ]. The frequency deviation Δf (t) may be a deviation of the frequency Δf (t) from the expected value E [ · ].

$$\text{Δ} P \left(t\right) = P \left(t\right) - \text{E} \left[P\right] \qquad \text{(5a)}$$

$$\text{Δ} f \left(t\right) = f \left(t\right) - \text{E} \left[f\right] \qquad \text{(5b)}$$

The expected value E [ · ] may be simply set as the last time value. At this time, Equation (5a) and Equation (5b) are represented as Equation (6a) and Equation (6b).

$$\text{Δ} P \left(t\right) = P \left(t\right) - P \left(t - \text{Δ} t\right) \qquad \text{(6a)}$$

$$\text{Δ} f \left(t\right) = f \left(t\right) - f \left(t - \text{Δ} t\right) \qquad \text{(6b)}$$

The calculation of the adjustment power is possible by using a method other than those described in Equations (2), (3), and (4). For example, according to the principle of the frequency adjustment shown in Equation (1), as in Equation (7), when the temporal change in the effective electric power ΔP has an opposite direction with respect to the temporal change in the frequency Δf, the ΔP is regarded as the positive adjustment power, and when it is in the same direction, it may be regarded as a negative adjustment power.

$$\text{Δ} {P}_{\text{R}} \left(t\right) = - sgn \left(\text{Δ} f \left(t\right)\right) ⋅ Δ P \left(t\right) \qquad \text{(7)}$$

A value obtained by integrating the above result for 24 hours by using Equation (4) may be defined as the adjustment electric power amount for one day.

As described above, in the related art, when the value of the frequency deviation Δf is small, the adjustment power tends to be underestimated. For example, it is considered a case where there is a power source having a rated output value of “100 MW”, the power source is operated at “50 MW” at 6 am in the morning, and the output is increased to “100 MW” at 12 pm in the afternoon. When the time interval of measurement by the measurement equipment is 100 ms, the output change ΔP per step is only “(100 MW - 50 MW) ÷ 6 ÷ 3600 ÷ 10 = 231 [W]”. In Equation (1), assuming that the reference frequency fₙ is “60 Hz” and the speed adjustment rate δ is “0.03” then “Δf = 4.2 x 10⁻⁶ [Hz]” is satisfied, and in common sense, it is a range that is embedded in a measurement error.

For example, as in Equation. (8), an adverse effect, in which noise that is unrelated to the frequency measured value f or the effective electric power measured value P, is superimposed on the frequency will be described.

$$\text{Δ} w ∼ \text{N} \left(0 , {σ}_{\text{Δ} w}^{2}\right) \qquad \text{(8)}$$

Assuming that the true frequency measured value Δf includes noise Δw, which is represented by a normal distribution having an average of “0” and a dispersion of “σ_{Δw}²”, in Equation (2), “σ_{Δw}” becomes larger than the measured value Δf as in Equation (9). That is, as a ratio of “σ_{Δw}” with respect to “| Δf |” increases, the adjustment power coefficient kₚ gradually approaches “0”.

$$\begin{matrix}{k}_{p} = \frac{{\sum }_{t} \text{Δ} P \left(t\right) ⋅ \left(\text{Δ} f \left(t\right) + \text{Δ} w \left(t\right)\right)}{{\sum }_{t} {\left(\text{Δ} f \left(t\right) + \text{Δ} w \left(t\right)\right)}^{2}} \\ = \frac{{\sum }_{t} \text{Δ} P \left(t\right) ⋅ \text{Δ} f \left(t\right)}{{\sum }_{t} \left(\text{Δ} f {\left(t\right)}^{2} \text{+} {σ}_{\text{Δ} w}^{2}\right)} \\ \to 0 \left(\left|\text{Δ} f\right| {σ}_{\text{Δ} w}^{- 1} \to 0\right)\end{matrix} \qquad \text{(9)}$$

As described above, when “| Δf |σ_{Δw}⁻¹” approaches 0, the adjustment power coefficient kₚ also becomes “0”, and it becomes difficult to correctly calculate the adjustment power.

Similarly, Equation (7) is represented as Equation (10) when a value obtained by adding the noise w to the true frequency f is measured.

$$\begin{matrix}\text{Δ} {P}_{\text{R}} \left(t\right) = - sgn \left(\text{Δ} f \left(t\right) + w \left(t\right)\right) Δ P \left(t\right) \\ \to - sgn \left(w \left(t\right)\right) ⋅ Δ P \left(t\right) \left(\left|\text{Δ} f\right| {σ}_{\text{Δ} w}^{- 1} \to 0\right)\end{matrix} \qquad \text{(10)}$$

When the above result is integrated for a sufficiently long time, the value becomes zero as in Equation (11). As described above, when there is noise in the measured value of the frequency, it becomes difficult to accurately measure the component of the supply and demand adjustment power that varies slowly with time, such as daily demand variation, as the adjustment electric power amount.

$$\begin{matrix}{W}_{\left[{t}_{i n i ,} {t}_{t e r}\right]} = {\sum }_{t = {t}_{i n i} , {t}_{i n i} + \text{Δ} t , ⋯ , {t}_{t e r}} \text{Δ} {P}_{\text{R}} \left(t\right) ⋅ \text{Δ} t \\ \to {\sum }_{t = {t}_{i n i} , {t}_{i n i} + \text{Δ} t , ⋯ , {t}_{t e r}} \text{−} \text{sgn} \left(w \left(t\right)\right) ⋅ Δ P \left(t\right) ⋅ \text{Δ} t \left(\left|\text{Δ} f\right| {σ}_{\text{Δ} w}^{- 1} \to 0\right) \\ = 0\end{matrix} \qquad \text{(11)}$$

On the other hand, for rapid supply and demand variation, frequency variations are also rapid. Therefore, a difference “Δf (t) + Δw (t) ’” between the frequency “f (t-1) + w(t-1)” measured last time and the frequency “f(t) + w(t)″ measured this time is, “| Δf(t) | >> | Δw (t) |”, so that the influence of the measurement noise does not appear on the surface and the above-mentioned problem does not occur.

As described above, in the related art, it is possible to accurately measure the adjustment power corresponding to the short-cycle supply and demand variation, but it is difficult to measure the adjustment power corresponding to the long-cycle supply and demand variation.

The adjustment power measuring system 1 according to the present embodiment is for accurately capturing a component in which the variation in the electric power supply and demand is slow, and is capable of measuring the supply and demand adjustment power of each of consumers C or each of power generation companies G based on the electric power demand (or the electric power supply) of the entire electric power system. In order to measure the adjustment power corresponding to the long-cycle supply and demand variation, the adjustment power measuring system 1 according to the present embodiment has a functional configuration as described below in each of the measurement equipment 50 and the server.

### (Functional Configuration of Measurement Equipment)

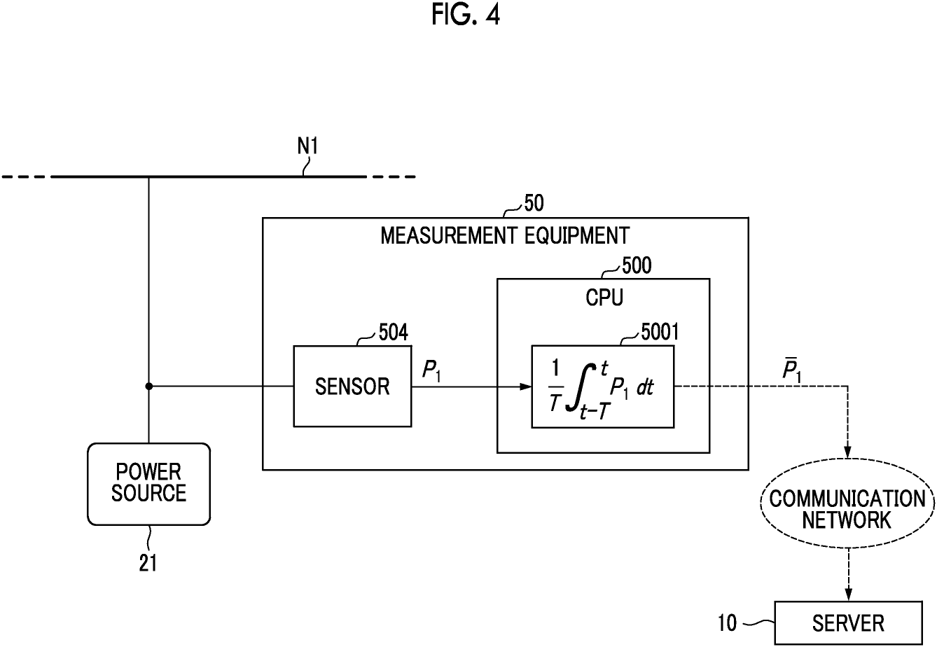

FIG. 4 is a block diagram illustrating a functional configuration of the measurement equipment according to the first embodiment of the present disclosure.

FIG. 4 illustrates, as an example, the measurement equipment 50 that measures the effective electric power output by the power source 21 to the first power transmission and distribution network N1 at the connection point between the power source 21 of the power generation company G1 and the first power transmission and distribution network N1.

The measurement equipment 50 measures the effective electric power P₁ supplied by the adjustment power providing means (the power source of the power generation company G, the load of the consumer C, the second power transmission and distribution network N2 managed by another system operator T2, or the like) to the first power transmission and distribution network N1 by using the sensor 504. In the example in FIG. 4, the measurement equipment 50 measures the effective electric power P₁ supplied by the power source 21 of the power generation company G to the first power transmission and distribution network N1.

Although the details will be described later, the server 10 calculates the electric power demand (or the electric power supply) of the entire electric power system for each predetermined time T, based on the effective electric power or the like acquired from the measurement equipment 50. For example, 1 minute is appropriate as the time T. The frequency of measurement by the sensor 504 of the measurement equipment 50 is set to be sufficiently smaller than the time interval T for calculating the electric power demand of the entire electric power system, for example, 100 ms.

As illustrated in FIG. 4, the CPU 500 of the measurement equipment 50 includes an effective electric power acquisition unit 5001. The effective electric power acquisition unit 5001 acquires the effective electric power measured value P₁ from the sensor 504. The effective electric power acquisition unit 5001 calculates an average value P- (“P-” is P with an overbar) of the effective electric power from time t - T to time t for the acquired effective electric power measured value P₁ and transmits the average value P- to the server 10 of the system operator T1 at a frequency higher than the time T at the latest through the communication network. The average value P- of the effective electric power is equal to a value obtained by dividing the increment of the effective electric power amount from the time t - T to the time t by the time T. The same process is also performed on the measurement equipment 50 installed at the connection point with another adjustment power providing means (the power source of another power generation company G, the load of the consumer C, the second power transmission and distribution network N2, or the like).

In the process S100, the measurement equipment 50 may calculate an average value of the electric power amount (“T⁻¹W_{[t}₋_{T,} _{t]}”) instead of the average value P- of the effective electric power.

### (Functional Configuration of Server)

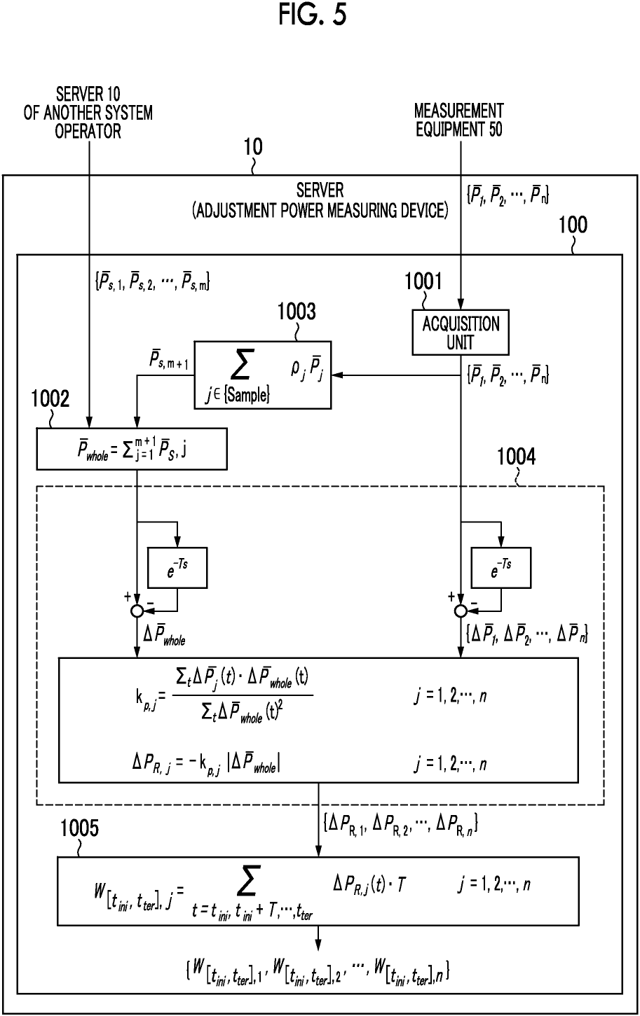

FIG. 5 is a block diagram illustrating a functional configuration of the server according to the first embodiment of the present disclosure.

As illustrated in FIG. 5, the CPU 100 of the server 10 (the adjustment power measuring device) includes an acquisition unit 1001, a first calculation unit 1002, a second calculation unit 1003, a measuring unit 1004 (a first measuring unit), and an integration unit 1005.

The acquisition unit 1001 acquires the effective electric power which is exchanged at the connection point between the adjustment power providing means (for example, the power source 21 of the power generation company G1) and the first power transmission and distribution network N1. The acquisition unit 1001 according to the present embodiment acquires the average value P- of the effective electric power from the measurement equipment 50.

The first calculation unit 1002 calculates the electric power demand or the electric power supply of the entire electric power system including the first power transmission and distribution network N1. In the following description, an example in which the first calculation unit 1002 calculates the electric power demand of the entire electric power system will be described.

The second calculation unit 1003 calculates the electric power demand or the electric power supply of the first power transmission and distribution network N1 based on the effective electric power (the average value P- of the effective electric power) acquired by the acquisition unit 1001. In the following description, an example in which the second calculation unit 1003 calculates the electric power demand of the first power transmission and distribution network N1 will be described. As a result, the server 10 of the system operator T1 can know the electric power demand in the entire area managed by the system operator T1 (an area where the electric power is transmitted and distributed by the first power transmission and distribution network N1).

The measuring unit 1004 measures adjustment power ΔP_{R} provided to the first power transmission and distribution network N1 by the adjustment power providing means based on the effective electric power (the average value P- of the effective electric power), and the electric power demand or the electric power supply of the electric power system. The adjustment power ΔP_{R}, which is measured by the measuring unit 1004 according to the present embodiment, is adjustment power for compensating for the long-cycle demand variation (hereinafter, also referred to as “first adjustment power”).

The integration unit 1005 calculates an adjustment power integrated value W obtained by integrating the adjustment powers measured by the measuring unit 1004 in a predetermined unit period. The predetermined unit period is, for example, 24 hours, 1 hour, 30 minutes, or the like. For example, in a case where the unit period is set to 24 hours, the integration unit 1005 can calculate a total adjustment power for one day of each of the adjustment power providing means.

The details of the process executed in each part of the server 10 will be described with reference to FIG. 5. The entire electric power system includes a plurality of system operators T. FIG. 5 represents a process in the server 10 of the system operator Tm + 1, assuming that there are m + 1 system operators T1, T2, .., Tm + 1 in total.

In the server 10 of the system operator Tm + 1, the acquisition unit 1001 acquires average values P-₁, P-₂, .., P-ₙ of the effective electric powers of each of the adjustment power providing means via the communication network from the measurement equipment 50 installed at the connection point with the adjustment power providing means included in each of the consumers C and the power generation companies G in the area managed by the server 10 of the system operator Tm + 1.

The second calculation unit 1003 calculates the electric power demand in the area (the first power transmission and distribution network N1) managed by the system operator Tm + 1. In the present embodiment, as in Equation (12), the second calculation unit 1003 sets a sum of the loads with respect to predetermined sample points {Sample} as the electric power demand P-_{s,m} _{+ 1} in the area. “p” is a load coefficient of the sample.

$${\overline{P}}_{S , m + 1} = {\sum }_{j ∈ \left\{\text{Sample}\right\}} {ρ}_{j} {\overline{P}}_{j} \qquad \text{(12)}$$

Also in the servers 10 from the other system operators T1 to Tm, a value of the electric power demand Pₛ in the area, which is managed by each system operator, is determined by using the calculation in Equation (12). The values are communicated with each other between the servers 10 of the system operators T via the communication network. The server 10 of the system operator Tm + 1 also receives the electric power demand P_{s,1}, P_{s,2}, .., P_{s,m} of the area, which is managed by each of the system operators T1 to Tm. A total sum of the demands in each area calculated by the first calculation unit 1002 is the electric power demand P_{whole} of the entire electric power system. The electric power demand P_{whole} is calculated by Equation (13).

$${\overline{P}}_{w h o l e} = {\sum }_{j = 1}^{m + 1} {\overline{P}}_{S , j} \qquad \text{(13)}$$

The electric power demand P_{whole} of the entire electric power system is updated at a cycle of every time T (for example, 1 minute). When the current time is defined as “t”, a difference from the last time value is represented by following Equation (14).

$$\text{Δ} {\overline{P}}_{w h o l e} \left(t\right) = {\overline{P}}_{w h o l e} \left(t\right) - {\overline{P}}_{w h o l e} \left(t - T\right) \qquad \text{(14)}$$

In order to implement the adjustment power measuring method according to the present embodiment, the load of communication or calculation is highest in the case where the electric power supply and demand of the entire electric power system are obtained. However, as described above, when the sample survey is used instead of the exhaustive survey of the electric power demand, the estimation becomes easier. Alternatively, since the number of power generation companies G (when the electric power is supplied from the second power transmission and distribution network N2 to the first power transmission and distribution network N1, the second power transmission and distribution network N2 is included) is smaller than the number of consumers C, when the electric power supply in the entire electric power system is used instead, the estimation of the electric power demand in the entire electric power system becomes easier. The electric power demand in the entire electric power system may be estimated by using a numerical model from a sample of the electric power demand or the electric power supply. By using such an estimation, it is possible to estimate the electric power demand in the entire electric power system, for example, every 1 minute. When a communication speed of the adjustment power measuring system 1 and a calculation speed of the server 10 are sufficient, the electric power demand of the first power transmission and distribution network N1 may be calculated by adding up the effective electric power of all consumers C (when the electric power is transmitted from the first power transmission and distribution network N1 to the second power transmission and distribution network N2, the second power transmission and distribution network N2 is included) connected to the first power transmission and distribution network N1.

Regarding the effective electric power, which is exchanged by the adjustment power providing means with the electric power system (the first power transmission and distribution network N1), a difference between the time t and the time t - T is as shown in following Equation (15). “e^{-Ts}” in FIG. 5 and Equation (15) is a transfer function representing a value before time T.

$$\begin{matrix}\text{Δ} {\overline{P}}_{j} \left(t\right) = {\overline{P}}_{j} \left(t\right) - {\overline{P}}_{j} \left(t - T\right) j = 1 , 2 , ⋯ , n \\ = \left(1 - {e}^{- T s}\right) {\overline{P}}_{j} \left(t\right) j = 1 , 2 , ⋯ , n\end{matrix} \qquad \text{(15)}$$

Focusing on one power generation company G, in a case where the demand on the electric power system is increased, that is, in a case where the value of ΔP-_{whole} becomes large on the negative side, and when the supply of the effective electric power is increased, that is, when ΔP-ⱼ becomes large on the positive side, the power generation company G contributes to the supply and demand adjustment. The measuring unit 1004 evaluates the relationship between the two by using following Equation (16). Equation (16) obtains the adjustment power coefficient Kₚ, which represents the influence degree of the variation in the effective electric power by the adjustment power providing means with respect to the variation in the electric power demand of the electric power system.

$${k}_{p , j} = \frac{{\sum }_{t} \text{Δ} {\overline{P}}_{j} \left(t\right) ⋅ \text{Δ} {\overline{P}}_{w h o l e} \left(t\right)}{{\sum }_{t} \text{Δ} {\overline{P}}_{w h o l e} {\left(t\right)}^{2}} j = 1 , 2 , ⋯ , n \qquad \text{(16)}$$

The measuring unit 1004 calculates the adjustment power ΔP_{R} of the adjustment power providing means by using Equation (17) .

$$\text{Δ} {P}_{\text{R,} j} \left(t\right) = - {k}_{p , j} \left|\text{Δ} {\overline{P}}_{w h o l e} \left(t\right)\right| j = 1 , 2 , ⋯ , n \qquad \text{(17)}$$

A value obtained by integrating the above result for a certain period of time, such as 24 hours, 1 hour, or 30 minutes for each time T, is the supply and demand adjustment electric power generated by the power source 21 of the power generation company G. This calculation is performed in the integration unit 1005 by using Equation (18) .

$${W}_{\left[{t}_{i n i} , {t}_{t e r}\right] , j} = {\sum }_{t = {t}_{i n i ,} {t}_{i n i} + T , ⋯ , {t}_{t e r}} \text{Δ} {P}_{\text{R,} j} \left(t\right) T j = 1 , 2 , ⋯ , n \qquad \text{(18)}$$

### (Effects of Action)

As described above, the adjustment power measuring device (the server 10) according to the present embodiment measures the adjustment power (the first adjustment power) provided by the adjustment power providing means to the first power transmission and distribution network based on the effective electric power of the adjustment power providing means, which is connected to the first power transmission and distribution network, and the electric power demand or the electric power supply of the entire electric power system including the first power transmission and distribution network.

As described above, when the adjustment power is measured using the frequency deviation Δf, the frequency deviation Δf may become a small value in a long-cycle supply and demand variation, and there is a possibility of underestimating the adjustment power. However, the adjustment power measuring device according to the present embodiment can appropriately measure how the effective electric power of the adjustment power providing means contributes to the long-cycle supply and demand variation in the electric power by using the electric power demand or the electric power supply of the entire electric power system instead of the frequency deviation Δf. Therefore, the adjustment power measuring device can accurately measure the sustainable adjustment power in a long cycle by the adjustment power providing means.

The adjustment power measuring device calculates the electric power demand or the electric power supply of the first power transmission and distribution network N1 based on the effective electric power of the plurality of adjustment power providing means and calculates the electric power demand or the electric power supply of the entire electric power system by calculating a total of the electric power demand or the electric power supply of the second power transmission and distribution network N2, which is acquired from the adjustment power measuring device of another system operator T, and the calculated electric power demand or the electric power supply of the first power transmission and distribution network N1.

In this way, the adjustment power measuring device can know the electric power demand or the electric power supply of the entire electric power system including both the first power transmission and distribution network N1, which is a management target, and the second power transmission and distribution network N2, which is a management target of another system operator T2.

The adjustment power measuring device may acquire, as a sample, the effective electric power of a part of the adjustment power providing means among the plurality of adjustment power providing means, which are connected to the first power transmission and distribution network N1, and may calculate the electric power demand or the electric power supply of the entire first power transmission and distribution network N1 from the sample effective electric power.

In this way, the adjustment power measuring device can reduce the amount of communication with the measurement equipment 50 and can also reduce the calculation amount of the adjustment power measuring device.

The adjustment power measuring device may calculate the adjustment power coefficient kₚ representing the influence degree of the effective electric power of the adjustment power providing means with respect to the variation in the electric power demand or the electric power supply of the electric power system, and may measure the adjustment power by using the calculated adjustment power coefficient kₚ.

In this way, the adjustment power measuring device can accurately measure the adjustment power.

The adjustment power measuring device may calculate an adjustment power integrated value obtained by integrating the measured adjustment powers in a predetermined unit period.

In this way, the adjustment power measuring device can easily know, for example, the daily adjustment power of each of the adjustment power providing means.

### Second Embodiment

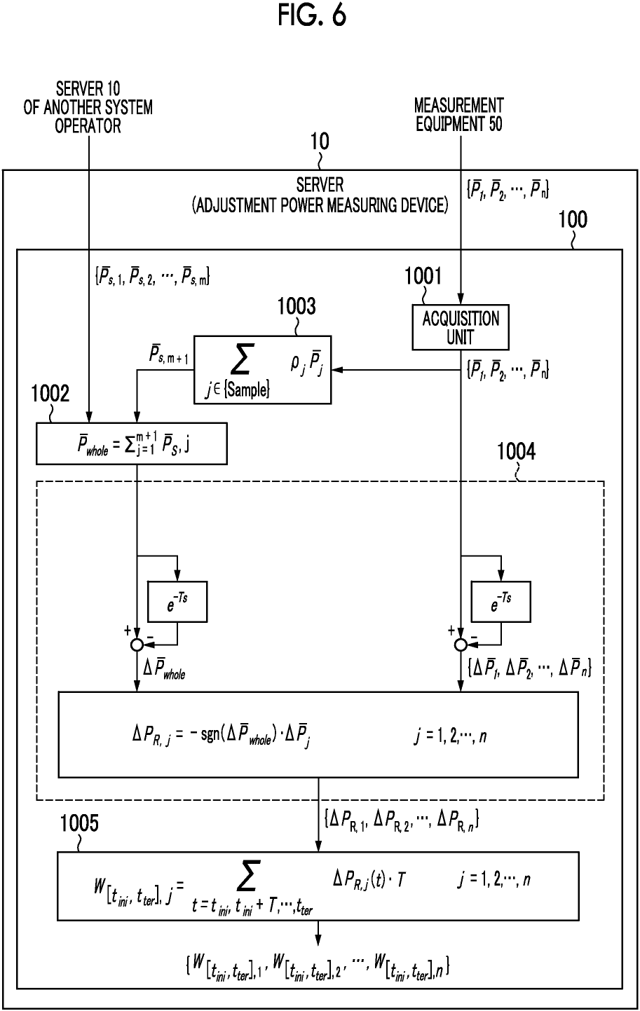

Next, an adjustment power measuring system according to a second embodiment of the present disclosure will be described with reference to FIG. 6.

The same reference numerals are given to the components common to those of the first embodiment, and a detailed description thereof will be omitted.

### (Functional Configuration of Server)

FIG. 6 is a block diagram illustrating a functional configuration of a server according to the second embodiment of the present disclosure.

As illustrated in FIG. 6, in the server 10 (the adjustment power measuring device) according to the present embodiment, the measuring unit 1004 calculates the adjustment power ΔP_{R} of the adjustment power providing means by using following Equation (19) instead of the above Equation (16) and Equation (17).

$$\text{Δ} {P}_{\text{R,} j} \left(t\right) = - sgn \left(\text{Δ} {\overline{P}}_{w h o l e} \left(t\right)\right) ⋅ \text{Δ} {\overline{P}}_{j} \left(t\right) j = 1 , 2 , ⋯ , n \qquad \text{(19)}$$

The other functions of the server 10 and the functions of the measurement equipment 50 are the same as those in the first embodiment.

### (Effects of Action)

As described above, the adjustment power measuring device (the server 10) according to the present embodiment uses a sign function to measure temporal change ΔP- in the effective electric power as positive or negative adjustment power in accordance with a direction of temporal change ΔP-_{whole} in the electric power demand or the entire electric power supply of the electric power system.

In this way, the adjustment power measuring device does not need to calculate the adjustment power coefficient kₚ, so that the calculation load can be reduced. As a result, for example, the adjustment power can be easily calculated for all the consumer C, the power generation company G, and the like including the household in the area (the first power transmission and distribution network N1), which are management targets of the adjustment power measuring device.

### Third Embodiment

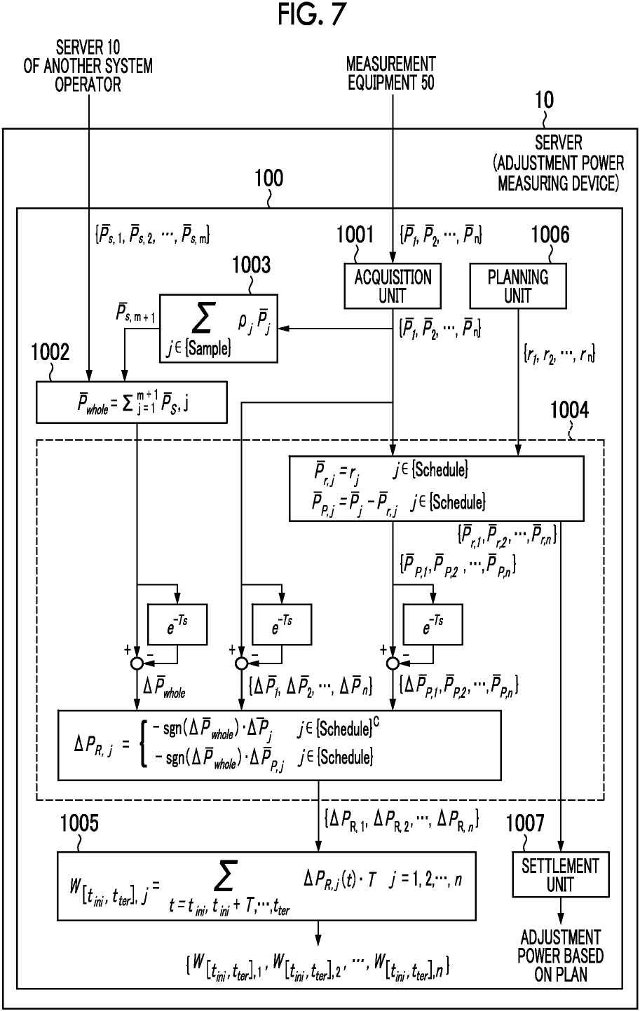

Next, an adjustment power measuring system according to a third embodiment of the present disclosure will be described with reference to FIG. 7.

The same reference numerals are given to the components common to those of the first embodiment and the second embodiment, and a detailed description thereof will be omitted.

### (Functional Configuration of Server)

FIG. 7 is a block diagram illustrating a functional configuration of a server according to the third embodiment of the present disclosure.

As illustrated in FIG. 7, the CPU 100 of the server 10 (the adjustment power measuring device) according to the present embodiment further includes a planning unit 1006 and a settlement unit 1007.

The planning unit 1006 sets a planned value of the electric power demanded or supplied by the adjustment power providing means of the first power transmission and distribution network N1, based on a predicted value of the electric power demand or the electric power supply of the electric power system. In the present embodiment, an embodiment in which the planning unit 1006 predicts the electric power demand of the entire electric power system and sets the planned value of the electric power supply and demand {r1, r2, .., rn} of each of the adjustment power providing means will be described as an example.

The settlement unit 1007 measures the adjustment power of the adjustment power providing means, in which the supply and demand adjustment is performed based on the planned value set by the planning unit 1006, and settles the compensation according to the adjustment power.

It is possible to predict the time history of the electric power demand of the entire electric power system based on the season, the day, or the like. For example, there is an existing technology in which the system operator T1 notifies the power generation company G1 of the prediction of the electric power demand for the day and a signal based on the prediction, the power generation company G1 supplies the electric power accordingly, and the measuring method of the supply and demand adjustment power is used based on the signal of the system operator T1 and the actual performance of the effective electric power supplied by the power generation company G1. Therefore, the planning unit 1006 predicts the electric power demand by using the known technology and sets the planned value of the electric power supply and demand. Similarly, the settlement unit 1007 measures the adjustment power of the adjustment power providing means, in which the supply and demand adjustment is performed based on the planned value, by using the known technology and settles the compensation according to the adjustment power.

Specifically, the adjustment power measuring device 10 according to the present embodiment performs the following processes on the adjustment power providing means participating in the supply and demand adjustment based on a plan.

In the area of the system operator T1, a set of the power generation company G, the consumer C, and the like who participate in the supply and demand adjustment based on the plan is represented by {Schedule}. The adjustment power measuring device 10 evaluates the adjustment power of a certain power generation company G1 or a consumer C, which are included in the set of {Schedule}, from two viewpoints of the supply and demand adjustment power p-ᵣ based on the time history of the planned electric power supply and the supply and demand adjustment power p-ₚ based on the electric power demand in the entire electric power system.

First, the measuring unit 1004 of the adjustment power measuring device 10 considers the supply and demand adjustment power p-ᵣ based on the former plan to coincide with the planned value r, for example, as in Equation (20). In addition to this, the measuring unit 1004 may determine the supply and demand adjustment power p-ᵣ based on the plan by using a sum of the loads with the planned value r and the actually supplied effective electric power P-.

$${\overline{p}}_{r , j} = {r}_{j} j ∈ \left\{\text{Schedule}\right\} \qquad \text{(20)}$$

On the other hand, the measuring unit 1004 obtains the supply and demand adjustment power p-ₚ, which is based on the electric power demand of the entire electric power system described in the first and second embodiments, by subtracting p-ᵣ from the actually supplied (demanded) effective electric power P— as in Equation (21).

$${\overline{p}}_{P , j} = {\overline{P}}_{j} - {\overline{p}}_{r , j} j ∈ \left\{\text{Schedule}\right\} \qquad \text{(21)}$$

The measuring unit 1004 calculates the supply and demand adjustment power (unplanned adjustment power), which is based on the electric power demand in the entire electric power system by the adjustment power providing means, by using Equation (22).

$$\text{Δ} {P}_{\text{R,} j} = - sgn \left(\text{Δ} {\overline{P}}_{w h o l e}\right) ⋅ \text{Δ} {\overline{p}}_{P , j} j ∈ \left\{\text{Schedule}\right\} \qquad \text{(22)}$$

The measuring unit 1004 calculates the adjustment power with respect to the adjustment power providing means {Schedule}^{c} that does not participate in the supply and demand adjustment based on the plan by using Equation (19) as in the second embodiment.

The settlement unit 1007 performs the measurement of the adjustment power and the settlement of the compensation for the supply and demand adjustment power p-ᵣ, which is based on the time history of the planned electric power supply, by using a known method.

### (Effects of Action)

As described above, the adjustment power measuring device (the server 10) according to the present embodiment sets the planned value of the electric power demanded or supplied by each of the adjustment power providing means based on the predicted value of the electric power demand or the electric power supply and measures the supply and demand adjustment power (the first adjustment power), which is based on the electric power demand in the entire electric power system by the adjustment power providing means, by using a value obtained by subtracting the planned value from the effective electric power, for the adjustment power providing means performing demand or supply of the electric power according to the planned value.

In the related art, the supply and demand adjustment power based on the planned value is measured, but the adjustment power for compensating the supply and demand variation in the unplanned electric power system is not measured. However, by having the above characteristics, when the adjustment power providing means exerts the adjustment power with respect to the supply and demand variation in the electric power system in addition to the planned value, the adjustment power measuring device according to the present embodiment can appropriately measure the adjustment power.

The adjustment power measuring device may further include a settlement unit 1007 that measures the supply and demand adjustment power based on the planned value and settles the compensation thereof. As a result, the adjustment power measuring device can appropriately measure both the supply and demand adjustment power, which is based on the planned value, and the unplanned supply and demand adjustment power.

In the present embodiment, an embodiment in which the measuring unit 1004 measures the adjustment power by using the sign function as in the second embodiment has been described as an example, but the present disclousre is not limited thereto. As in the first embodiment, the measuring unit 1004 may measure the adjustment power by using the adjustment power coefficient kₚ.

### Fourth Embodiment

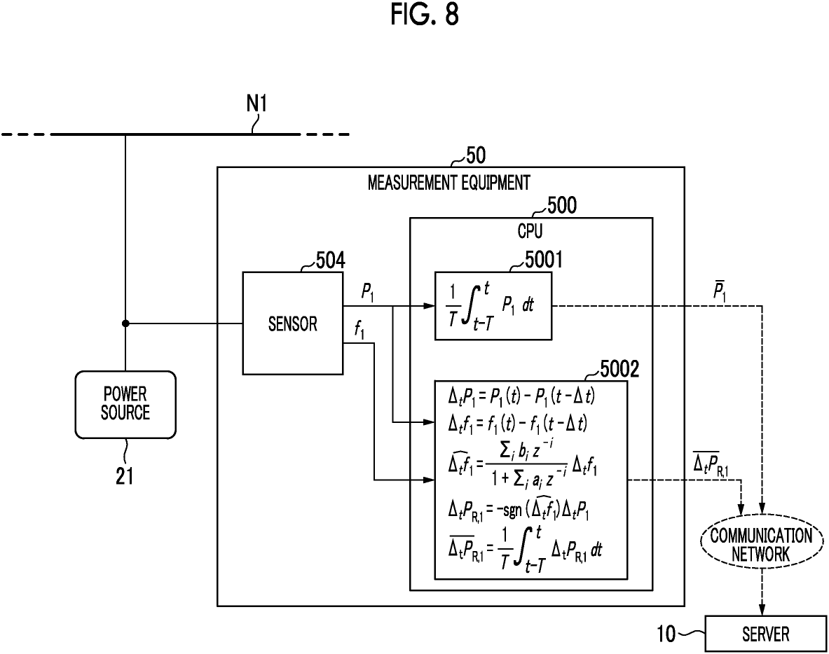

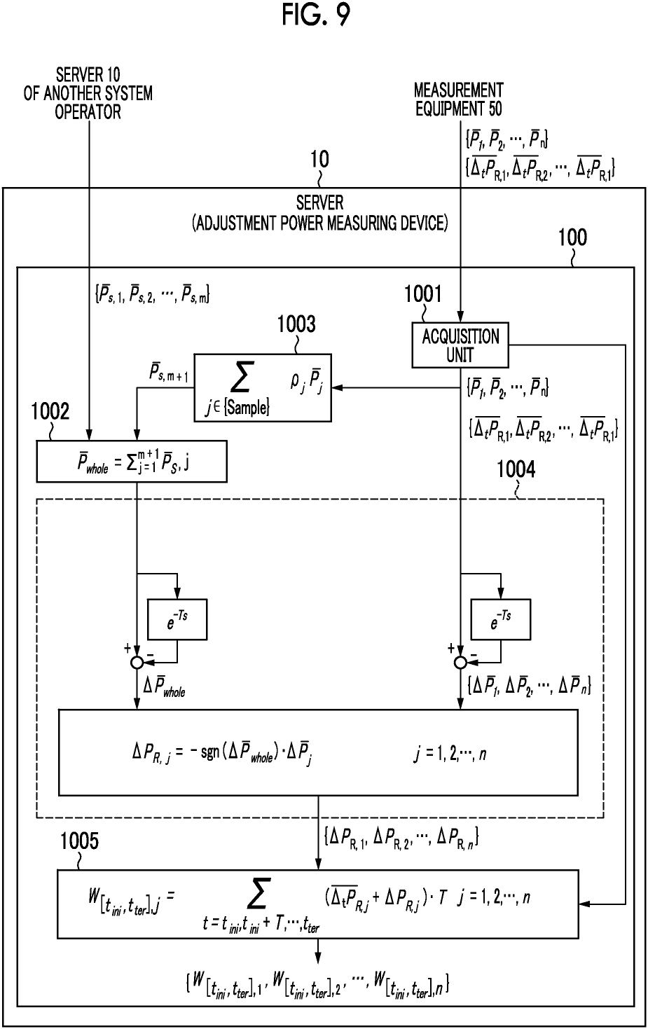

Next, an adjustment power measuring system according to a fourth embodiment of the present disclosure will be described with reference to FIGS. 8 to 9.

The same reference numerals are given to the components common to those of the first to third embodiments, and a detailed description thereof will be omitted.

### (Functional Configuration of Measurement Equipment)

FIG. 8 is a block diagram illustrating a functional configuration of the measurement equipment according to the fourth embodiment of the present disclosure.

As illustrated in FIG. 8, a sensor 504 of the measurement equipment 50 according to the present embodiment measures the frequency f₁ of the first power transmission and distribution network N1 at the connection point in addition to the effective electric power P₁, which is exchanged at the connection point between the adjustment power providing means and the first power transmission and distribution network N1. Similar to the first embodiment, the frequency of measurement is set to be sufficiently smaller than the time interval T in which the server 10 calculates the electric power demand of the entire electric power system, such as 100 ms.

The effective electric power acquisition unit 5001 of the measurement equipment 50 calculates an average value P- of the effective electric power from time t - T to time t for the effective electric power P₁ as in the first embodiment and transmits the average value P- to the server 10 of the system operator T1 at a frequency higher than the time T at the latest through the communication line.

In addition, the CPU 500 of the measurement equipment 50 further includes a short-cycle component measuring unit 5002 (the second measuring unit). The short-cycle component measuring unit 5002 measures a short-cycle component (the adjustment power with respect to the short-cycle supply and demand variation in a cycle substantially 3 to 5 seconds. Hereinafter also referred to as “second adjustment power”) of the adjustment power at a sufficiently small cycle, such as 100 ms, as compared with the time interval T at which the server 10 calculates the electric power demand of the entire electric power system, for example. As a method for measuring the short-cycle component of the adjustment power, for example, the technology described in PTL 1 is used. Specifically, a time difference interval is positively represented as “Δt”, and a time difference between the effective electric power P and the frequency f is represented in Equations (23) and (24), respectively. In Equations (23) and (24), “j” represents each of the adjustment power providing means such as the consumer C or the power generation company G in the area of the system operator T1, and assumed that there are n in total.

$${Δ}_{t} {P}_{j} \left(t\right) = {P}_{j} \left(t\right) - {P}_{j} \left(t - \text{Δ} t\right) j = 1 , 2 , ⋯ , n \qquad \text{(23)}$$

$${Δ}_{t} {f}_{j} \left(t\right) = {f}_{j} \left(t\right) - {f}_{j} \left(t - \text{Δ} t\right) j = 1 , 2 , ⋯ , n \qquad \text{(24)}$$

When the above result is applied to above Equation (7), the short-cycle component of the adjustment power of each of the adjustment power providing means is represented as Equation (25).

$${\text{Δ}}_{t} {P}_{\text{R,} j} = - sgn \left({Δ}_{t} {f}_{j} \left(t\right)\right) ⋅ {Δ}_{t} {P}_{j} \left(t\right) j = 1 , 2 , ⋯ , n \qquad \text{(25)}$$

As in the first embodiment, the measurement equipment 50 transmits a time average value of the adjustment power for each time cycle T to the server 10 of the system operator T1. The time average value is calculated by using Equation (26).

$${\overline{{\text{Δ}}_{t} P}}_{\text{R,} j} = \frac{1}{T} {\int }_{t - T}^{t} {\text{Δ}}_{t} {P}_{\text{R,} j} d t \qquad \text{(26)}$$

In Equation (25), in order not to mix the long-cycle component in the measurement of the short-cycle component of the adjustment power, the short-cycle component measuring unit 5002 of the measurement equipment 50 may use a frequency difference after removing the sustainable component of the time difference using a high-pass filter as in Equation (27).

$$\hat{{\text{Δ}}_{t} {f}_{1}} = \frac{{\sum }_{i} {b}_{i} {z}^{- 1}}{1 + {\sum }_{i} {a}_{i} {z}^{- 1}} {\text{Δ}}_{t} {f}_{1} \qquad \text{(27)}$$

In Equation (27), “a” and “b” are coefficients that determine the pass characteristics of the high-pass filter. “z⁻¹” is a unit delay operator of a digital filter. When the filter is applied, Equation (25) becomes as shown in Equation (28).

$${\text{Δ}}_{t} {P}_{\text{R,} j} = - sgn \left(\hat{{\text{Δ}}_{t} {f}_{1}} \left(t\right)\right) ⋅ {Δ}_{t} {P}_{j} \left(t\right) j = 1 , 2 , ⋯ , n \qquad \text{(28)}$$

### (Functional Configuration of Server)

FIG. 9 is a block diagram illustrating a functional configuration of a server according to the fourth embodiment of the present disclosure.

As illustrated in FIG. 9, in the server 10 (the adjustment power measuring device) according to the present embodiment, the acquisition unit 1001 further acquires a short-cycle component of the adjustment power calculated by using Equation (26) in the measurement equipment 50. By doing so, the integration unit 1005 of the server 10 integrates the time average value of the short-cycle component of the adjustment power (the second adjustment power) acquired from the measurement equipment 50 and the long-cycle component of the adjustment power (the first adjustment power) measured by the measuring unit 1004, by using Equation (29). In another embodiment, in Equation (29), a sum of the loads of the time average value of the short-cycle component (the second adjustment power) and the long-cycle component of the adjustment power (the first adjustment power) measured by the measuring unit 1004 may be integrated.

$${W}_{\left[{t}_{i n i} , {t}_{t e r}\right] , j} = {\sum }_{t = {t}_{i n i ,} {t}_{i n i} + T , ⋯ , {t}_{t e r}} \left({\overline{{\text{Δ}}_{t} P}}_{\text{R,} j} \text{+Δ} {P}_{\text{R,} j}\right) ⋅ T j = 1 , 2 , ⋯ , n \qquad \text{(29)}$$

FIG. 9 illustrates an example in which the measuring unit 1004 measures the long-cycle component of the adjustment power by using the same method as in the second embodiment, but the present disclosure is not limited thereto. In another embodiment, the measuring unit 1004 may measure the long-cycle component of the adjustment power by using the same method as in the first embodiment. The measuring unit 1004 may measure the long-cycle component of the unplanned adjustment power based on the planned value set by the planning unit 1006, as in the third embodiment.

### (Effects of Action)

As described above, in the adjustment power measuring system 1 according to the present embodiment, the measurement equipment 50 measures the short-cycle component of the adjustment power (the second adjustment power) of the adjustment power providing means, based on the frequency at the connection point and the effective electric power exchanged at the connection point. The adjustment power measuring device (the server 10) calculates the adjustment power integrated value for a predetermined unit period of the adjustment power providing means based on the short-cycle component of the adjustment power (the second adjustment power) of the adjustment power providing means acquired from the measurement equipment 50 and the short-cycle component of the adjustment power measured by the measuring unit 1004.

In this way, the adjustment power measuring system 1 can evaluate both the short-cycle component and the long-cycle component of the adjustment power of each of the adjustment power providing means in the adjustment power measuring device.

### Fifth Embodiment

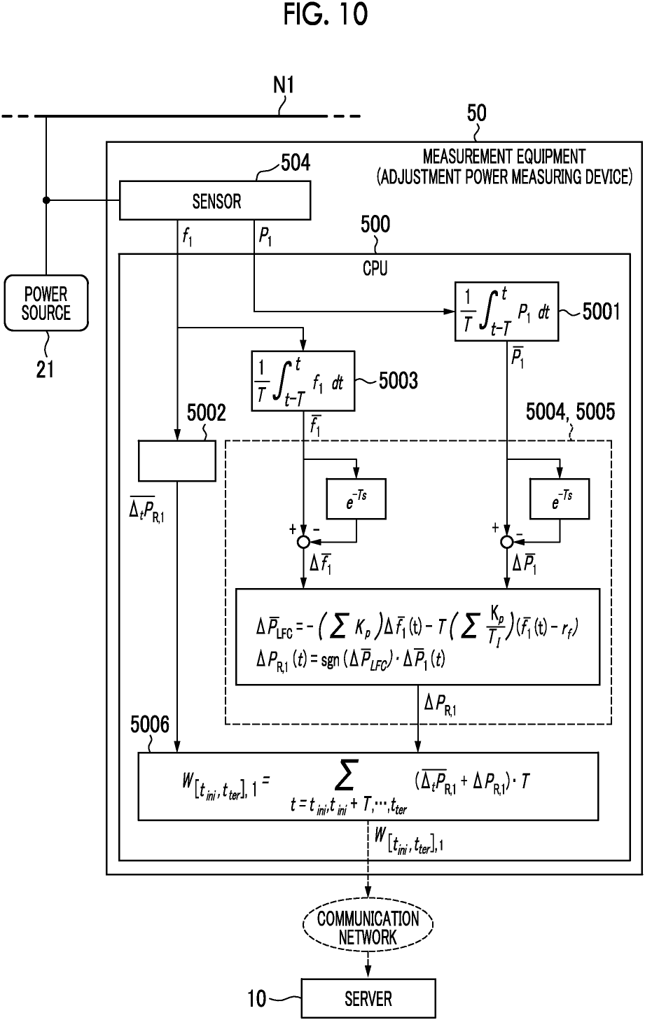

Next, an adjustment power measuring system according to a fifth embodiment of the present disclosure will be described with reference to FIG. 10.

The same reference numerals are given to the components common to those of the first to fourth embodiments, and a detailed description thereof will be omitted.

### (Functional Configuration of Measurement Equipment)

FIG. 10 is a block diagram illustrating a functional configuration of the measurement equipment according to the fifth embodiment of the present disclosure.

As illustrated in FIG. 10, in the adjustment power measuring system 1 according to the present embodiment, the measurement equipment 50 functions as an “adjustment power measuring device” that measures the adjustment power of the adjustment power providing means (in the example in FIG. 10, the power source 21 of the power generation company G) connected to the power transmission and distribution network N at the connection point where the measurement equipment 50 is installed. The sensor 504 of the measurement equipment 50 according to the present embodiment measures a frequency measured value f at the connection point and an effective electric power measured value P exchanged between the adjustment power providing means and the power transmission and distribution network N at the connection point.

The CPU 500 of the measurement equipment 50 (the adjustment power measuring device) according to the present embodiment further includes a frequency acquisition unit 5003, an LFC output calculation unit 5004 (the first calculation unit), a long-cycle component measuring unit 5005 (the first measuring unit), and an integration unit 5006, in addition to the effective electric power acquisition unit 5001 and the short-cycle component measuring unit 5002 (the second measuring unit) of each embodiment described above. In the present embodiment, the effective electric power acquisition unit 5001 and the frequency acquisition unit 5003 are also simply referred to as “acquisition units”. The short-cycle component measuring unit 5002 and the long-cycle component measuring unit 5005 are collectively referred to as a “measuring unit”.

The effective electric power acquisition unit 5001 (the acquisition unit) acquires an effective electric power measured value P₁ from the sensor 504 and calculates an average value P- of the effective electric power from the time t - T to the time t, as in each of the above-described embodiments.

The frequency acquisition unit 5003 (the acquisition unit) acquires a frequency measured value f₁ from the sensor 504. The frequency acquisition unit 5003 calculates an average value f- of frequencies from time t - T to time t (“f-” is f with an overbar) for the acquired frequency measured value f₁.

The LFC output calculation unit 5004 (the first calculation unit) calculates variation in the electric power demand or the electric power supply of the entire electric power system ΔP-_{LFC}, based on the average value f-of the frequencies and the reference value of the frequency set in the first power transmission and distribution network N1 (hereinafter also referred to as a “reference frequency”).

The long-cycle component measuring unit 5005 (the first measuring unit) measures a long-cycle component of the adjustment power (the first adjustment power) ΔP_{R} provided by the adjustment power providing means to the first power transmission and distribution network N1, based on the effective electric power (the average value P- of the effective electric power) acquired by the effective electric power acquisition unit 5001 and the electric power demand or the electric power supply of the electric power system calculated by the LFC output calculation unit 5004.

As in the fourth embodiment, the short-cycle component measuring unit 5002 (the second measuring unit) measures the short-cycle component of the adjustment power (the second adjustment power) that responds to the supply and demand variation in a cycle shorter than that of the first adjustment power, based on the frequency measured value f₁ and the effective electric power measured value P₁.

The integration unit 5006 calculates the adjustment power integrated value W provided by the adjustment power providing means for a predetermined unit period, based on the long-cycle component of the adjustment power (the first adjustment power) calculated by the long-cycle component measuring unit 5005 and the short-cycle component of the adjustment power (the second adjustment power) calculated by the short-cycle component measuring unit 5002. The adjustment power integrated value W, which is calculated by the integration unit 5006, is transmitted to the server of the system operator T1 via the communication network.

The adjustment power measuring device in the related art as in PTL 1 measures the adjustment power based on a relationship between the frequency and the effective electric power in a case where a governor-free (GF) mode is used. In the governor-free mode, the frequency deviation Δf and the adjustment power ΔP are proportional to each other as in above Equation (1). Under the governor-free mode, in order to generate an additional large effective electric power P, that is, it is required that the value of Δf be large. Therefore, as described above, it is difficult to use Δf as an index of demand variation because the value of Δf becomes extremely small for a long cycle variation such as daily electric power demand variation. Therefore, in the above-described first and second embodiments, the technology for directly measuring the electric power demand of the entire electric power system has been described.

For each of the above-described embodiments, in the present embodiment, technology that makes it possible to measure a long-cycle component included in the demand variation based on the load frequency control (LFC) will be described. Since the load frequency control targets the long-cycle component of substantially several minutes to 30 minutes, a part of the long-cycle variation component such as daily demand variation is compensated by the load frequency control.

Generally, a proportional integration controller (a PI controller) is used for the load frequency control. In the following, the operation of the load frequency control will be explained using a transfer function with the equilibrium state, as an origin point, where the frequency measured value f and the fixed reference frequency r_{f} match. The controller of the load frequency control is represented by a transfer function as in Equation (30). When the effective electric power, which is generated by the power source 21 of the power generation company G that follows the load frequency control, is described as “P_{LFC}”, the variation from a value “P_{LFC0}” at the equilibrium point is represented by following Equation (30).

$${P}_{L F C} - {P}_{L F C O} = - {K}_{p} \left(1 + \frac{1}{{T}_{I} s}\right) \left(f - {r}_{f}\right) \qquad \text{(30)}$$

In Equation (30), “Kₚ” and “T_{I}” are proportional gain and integrated time constant and are used for adjusting the load frequency control. “s” is a Laplace operator. On the other hand, when the effective electric power, which is generated by the power source 21 of the power generation company G that operates in governor-free operation is described as “P_{GF}”, the variation from a value “P_{GFO}” in the equilibrium state is represented by Equation (31) .

$${P}_{G F} - {P}_{G F 0} = - \frac{1}{δ} \frac{{P}_{n}}{{f}_{n}} f \qquad \text{(31)}$$

There is also a value P_{D0} in the equilibrium state for the electric power demand P_{D}. Equation (32) is satisfied because the total sum of the suppliers (the power generation company G or the like) and the total sum of the consumers (the consumer C or the like) are balanced in the equilibrium state.

$$\left\{\begin{matrix}{\sum }_{j ∈ \left\{\text{Supply}\right\}} \left({P}_{L F C 0 , j} + {P}_{G F 0 , j}\right) - {\sum }_{j ∈ \left\{\text{Demand}\right\}} {P}_{D 0 , j} = 0 \\ {P}_{0 , w h o l e} = {\sum }_{j ∈ \left\{\text{Demand}\right\}} {P}_{D 0 , j}\end{matrix}\right) \qquad \text{(32)}$$

In Equation (32), {Supply} represents a supplier and {Demand} represents a consumer. The total sum of demands is represented by “P_{D}, _{whole}” and a value in the equilibrium state is represented by “P_{D0}, _{whole}” . Among a large number of power generation companies G connected to the electric power system, there is one that operates at a constant output without performing the load frequency control or the governor-free operation. The power source 21 of these power generation companies G will also be uniformly handled by using Equation (30) or Equation (31) as “Kₚ = 0” or “δ-1 ₌ 0”.

Equation (33) is satisfied for the variation in the frequency “δf = f - r_{f}” and the variation in the demand “δP_{D}, _{whole} = P_{D}, _{whole} - P_{D0}, _{whole}”. In Equation (33), “J” with the sigma symbol on the left side is the total sum of inertia of the electric power system. The sigma in the first term of the right side numerator represents the total sum of the suppliers, and the second term represents the total sum of the consumers.

$$4 {π}^{2} {f}_{n} \sum J s \text{δ} f = - \sum \left({K}_{p} \left(1 + \frac{1}{{T}_{I} s}\right) \text{δ} f + \frac{1}{δ} \frac{{P}_{n}}{{f}_{n}} \text{δ} f\right) - \text{δ} {P}_{D , w h o l e} \qquad \text{(33)}$$

Equation (34) is obtained by solving the above Equation for “δf”. The frequency variation in the entire electric power system is represented by a second-order system as in Equation (34). Such simplification is possible because the demand variation to be handled is focused on the frequency variation caused by sustainable variation, that is, slow demand variation that affects the entire electric system.

$$\text{δ} f = \frac{- \text{δ} {P}_{D , w h o l e}}{4 {π}^{2} {f}_{n} \sum I s + \left(\sum {K}_{p} + \sum \frac{1}{δ} \frac{{P}_{n}}{{f}_{n}}\right) + \left(\sum \frac{{K}_{p}}{{T}_{I}}\right) \frac{1}{s}} \qquad \text{(34)}$$

Here, as in Equation (35), the supply and demand imbalance is represented by the symbol “eₚ”.

$$\begin{matrix}{e}_{P} = \sum \left({P}_{L F C 0} - {K}_{p} \left(1 + \frac{1}{{T}_{I} s}\right) \left(f - {r}_{f}\right)\right) + \sum \left({P}_{G F 0} - \frac{1}{δ} \frac{{P}_{n}}{{f}_{n}} f\right) \\ - \left({P}_{D , w h o l e} - {P}_{D 0 , w h o l e}\right) \\ = \sum - {K}_{p} \left(1 + \frac{1}{{T}_{I} s}\right) \text{δ} f + \sum \left(- \frac{1}{δ} \frac{{P}_{n}}{{f}_{n}}\right) \text{δ} f - \text{δ} {P}_{D , w h o l e}\end{matrix} \qquad \text{(35)}$$

In the derivation of the second row in Equation (35), it is used that the frequency coincides with “r_{fo}” in the equilibrium state. From Equation (35) and Equation (34), a transfer function with demand variation as an input and supply and demand imbalance as an output can be obtained as in Equation (36). The demand variation is the third term on the right side of the second row in Equation (35), that is, the demand variation itself of the consumer. The supply and demand imbalance is the entire right side of the second row in Equation (35), and is an error remaining after the supplier compensates for the demand variation with the adjustment power such as the load frequency control or the governor-free operation.

$$\text{δ} f = \frac{- \text{δ} {P}_{D , w h o l e}}{4 {π}^{2} {f}_{n} \sum I s + \left(\sum {K}_{p} + \sum \frac{1}{δ} \frac{{P}_{n}}{{f}_{n}}\right) + \left(\sum \frac{{K}_{p}}{{T}_{I}}\right) \frac{1}{s}} \qquad \text{(36)}$$

An object of the present embodiment is to measure the adjustment power with respect to the long-cycle sustainable demand variation such as daily demand variation. Hereinafter, it will be described that the long-cycle sustainable demand variation in the entire electric power system can be estimated from the output P_{LFC} of the load frequency control. A set value of the supply and demand imbalance with respect to the sustainable demand variation is calculated by simulating the long-cycle sustainable demand variation with a ramp function. Using the final value theorem, when the set value of the supply and demand imbalance with respect to the sustainable demand variation is calculated, a value becomes “0” as shown in Equation (37).

$$\begin{matrix}{lim}_{s \to 0} s \frac{1}{{s}^{2}} \frac{{e}_{P}}{δ {P}_{D , w h o l e}} = {lim}_{s \to 0} \\ \frac{{\left(2 π {f}_{n}\right)}^{2} \sum J}{4 {π}^{2} {f}_{n} \sum J s + \left(\sum {K}_{p} + \sum \frac{1}{δ} \frac{{P}_{n}}{{f}_{n}}\right) + \left(\sum \frac{{K}_{p}}{{T}_{I}}\right) \frac{1}{s}} \\ = 0\end{matrix} \qquad \text{(37)}$$

Therefore, the sustainable demand variation and the supply are balanced as shown in Equation (38).

$$\sum \text{δ} {P}_{L F C} + \sum \text{δ} {P}_{G F} - δ {P}_{D , w h o l e} = 0 \qquad \text{(38)}$$

It will be shown below that this balance is due to the operation of the load frequency control. Equation (39) is obtained by calculating the output response of the load frequency control with respect to the unit step of the demand variation from the final value theorem.

$$\begin{matrix}{lim}_{s \to 0} s \frac{1}{s} \frac{\sum \text{δ} {P}_{L F C}}{δ {P}_{D , w h o l e}} = {lim}_{s \to 0} s \frac{1}{s} \frac{\sum \text{δ} {P}_{L F C}}{\text{δ} f} \frac{\text{δ} f}{δ {P}_{D , w h o l e}} \\ = {lim}_{s \to 0} \frac{\sum {K}_{p} + \left(\sum \frac{{K}_{p}}{{T}_{I}}\right) \frac{1}{s}}{4 {π}^{2} {f}_{n} \sum J s + \left(\sum {K}_{p} + \sum \frac{1}{δ} \frac{{P}_{n}}{{f}_{n}}\right) + \left(\sum \frac{{K}_{p}}{{T}_{I}}\right) \frac{1}{s}} \\ = 1\end{matrix} \qquad \text{(39)}$$

Equation (39) represents that the total sum of the demand variations coincides with the total sum of the outputs of the load frequency control. As a precaution, Equation (40) calculates the final value of the governor-free output with respect to the unit step of the demand variation.

$$\begin{matrix}{lim}_{s \to 0} s \frac{1}{s} \frac{\sum \text{δ} {P}_{G F}}{δ {P}_{D , w h o l e}} = {lim}_{s \to 0} s \frac{1}{s} \frac{\sum \text{δ} {P}_{G F}}{\text{δ} f} \frac{\text{δ} f}{δ {P}_{D , w h o l e}} \\ = {lim}_{s \to 0} \frac{\sum \frac{1}{δ} \frac{{P}_{n}}{{f}_{n}}}{4 {π}^{2} {f}_{n} \sum J s + \left(\sum {K}_{p} + \sum \frac{1}{δ} \frac{{P}_{n}}{{f}_{n}}\right) + \left(\sum \frac{{K}_{p}}{{T}_{I}}\right) \frac{1}{s}} \\ = 0\end{matrix} \qquad \text{(40)}$$

As described above, since the final value of the governor-free output with respect to the demand variation is “0”, it is shown from Equation (38) and Equation (39) that the sustainable demand variation is balanced with the output of the load frequency control.

In the above-described first to fourth embodiments, the total sum of the demands in the electric power system is directly measured in order to detect the sustainable demand variation. However, as described in the present embodiment, the total sum of the sustainable demand variations coincides with the output of the load frequency control. By utilizing this property, it becomes possible to substitute the measurement of the total sum of the demands of the entire electric power system with the output of the load frequency control. Hereinafter, a specific measuring method executed by the measurement equipment 50 according to the present embodiment will be described. An example in which the measurement equipment 50 measures the adjustment power of the power source 21 managed by the power generation company will be described here.

Equation (41) is obtained by differentiating Equation (30) over time T. “Kₚ” and “T_{I}” with sigma symbols are values with respect to the entire electric power system, may be predetermined fixed values, and may be obtained from the server 10 or the like via a communication network, with values changed in accordance with the season, the time, the area, or the like.

$$Δ {P}_{L F C} = - \left(\sum {K}_{p}\right) Δ f - T \left(\sum \frac{{K}_{p}}{{T}_{I}}\right) \left(f - {r}_{f}\right) \qquad \text{(41)}$$

The measurement equipment 50 according to the present embodiment evaluates the sustainable adjustment power every time T (for example, 1 minute) as in each of the above-described embodiments. A time average value from the time t - T to the time t is used for the frequency and the effective electric power used to the evaluation of the adjustment power such that the influence of noise is removed.

The frequency acquisition unit 5003 calculates the time average value of the frequency f₁ by using Equation (42) .

$${\overline{f}}_{1} \left(t\right) = \frac{1}{T} {\int }_{t - T}^{t} {f}_{1} d t \qquad \text{(42)}$$

The LFC output calculation unit 5004 calculates a frequency difference by using Equation (43).

$$Δ {\overline{f}}_{1} \left(t\right) = {\overline{f}}_{1} \left(t\right) - {\overline{f}}_{1} \left(t - T\right) \qquad \text{(43)}$$

The LFC output calculation unit 5004 calculates an average value of the increment of the output of the load frequency control between the time t - T and the time t by using Equation (44). In the present embodiment, the value obtained by using Equation (44) is used as the electric power demand or the electric power supply of the entire electric power system.

$$Δ {\overline{P}}_{L F C} = - \left(\sum {K}_{p}\right) Δ {\overline{f}}_{1} \left(t\right) - T \left(\sum \frac{{K}_{p}}{{T}_{I}}\right) \left({\overline{f}}_{1} \left(t\right) - {r}_{f}\right) \qquad \text{(44)}$$

The long-cycle component measuring unit 5005 applies the value obtained by using Equation (44) to Equation (19) described in the second embodiment and measures the long-cycle component of the adjustment power by using Equation (45). The long-cycle component measuring unit 5005 may apply the value obtained by using Equation (44) to Equations (16) and (17) of the first embodiment and measure the long-cycle component of the adjustment power.

$$Δ {P}_{\text{R,1}} \left(t\right) = sgn \left(Δ {\overline{P}}_{L F C}\right) ⋅ Δ {\overline{P}}_{1} \left(t\right) \qquad \text{(45)}$$

The integration unit 5006 integrates the addition of the short-cycle component of the adjustment power measured by the short-cycle component measuring unit 5002 by using Equation (46) and measures the adjustment power of the power source 21 in the unit period. The process is the same as the process of the integration unit 1005 of the server 10 according to the fourth embodiment. In another embodiment, in Equation (46), a sum of the loads of the time average value of the short-cycle component (the second adjustment power) and the long-cycle component of the adjustment power (the first adjustment power) measured by the long-cycle component measuring unit 5005 may be integrated.

$${W}_{\left[{t}_{i n i} , {t}_{t e r}\right] , 1} = {\sum }_{t = {t}_{i n i} , {t}_{i n i} + T , ⋯ , {t}_{t e r}} \left({\overline{{Δ}_{t} P}}_{\text{R,1}} + Δ {P}_{\text{R,1}}\right) ⋅ T \qquad \text{(46)}$$

### (Effects of Action)

As described above, the adjustment power measuring device (the measurement equipment 50) according to the present embodiment calculates the electric power demand or the electric power supply of the entire electric power system based on the frequency at the connection point and the reference value of the frequency set in the first power transmission and distribution network N1.

In this way, by calculating and aggregating the electric power demand or the electric power supply of the power transmission and distribution network N in which each of the plurality of system operators T are management targets, the process of calculating the electric power demand or the electric power supply of the entire electric power system becomes unnecessary. Therefore, the calculation load on the server 10 of each system operator T can be reduced. Since communication between the servers 10 of each system operator T for each time T is not required, the traffic between the servers can be significantly reduced. Further, since the communication between the servers 10 is not required, the measurement equipment 50 at each connection point can autonomously measure the adjustment power of the adjustment power providing means.

### Sixth Embodiment

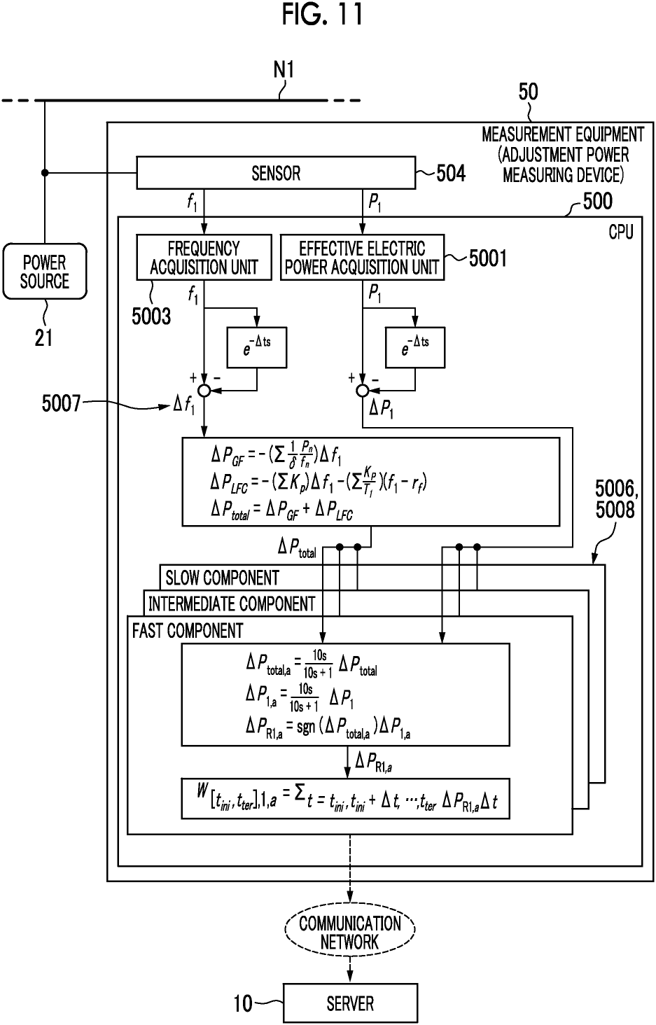

Next, an adjustment power measuring system according to a sixth embodiment of the present disclosure will be described with reference to FIG. 11.

The same reference numerals are given to the components common to those of the first to fifth embodiments, and a detailed description thereof will be omitted.

The demand of the electric power has a component with a different speed in variation and has various components with different speeds in variations in supply and demand adjustment power that respond to the component. For example, on page 42 of handout 4 of the 18th Supply and Demand Adjustment Market Study Subcommittee (Aug. 7, 2020) of the Organization for Cross-regional Coordination of Transmission Operators, it states that the supply and demand adjustment power is divided into five products with primary adjustment power (response time within 10 seconds), secondary adjustment power 1 or 2 (response time within 5 minutes), tertiary adjustment power 1 (response time within 15 minutes), and the tertiary adjustment power 2 (response time within 45 minutes), according to the speed of variation, and traded. Intuitively, a product having a quick response (for example, the primary adjustment power) has more value in supply and demand adjustment than a slow component (for example, the tertiary adjustment power 2), and the unit price of a trade is also high. In the present embodiment, in order to cope with a case where the unit price differs according to the speed of the adjustment power, it is possible to integrate the adjustment power corresponding to a classification by the speed of response, and possible to trade at the unit price set for each classification of the speed of response.

In the fifth embodiment described above, as in Equation (46), the integrated value of the adjustment power finally obtained is one, and it is not classified according to the speed of the response. Therefore, it is difficult to reflect the difference in speed in the unit price. On the other hand, in the present embodiment, a single or a plurality of classifications are set according to the speed of response, and an integrated value is obtained for each classification.

### (Functional Configuration of Measurement Equipment)

FIG. 11 is a block diagram illustrating a functional configuration of the measurement equipment according to the sixth embodiment of the present disclosure.

As illustrated in FIG. 11, the CPU 500 of the measurement equipment 50 (the adjustment power measuring device) according to the present embodiment functions as an effective electric power acquisition unit 5001 (the acquisition unit), a frequency acquisition unit 5003 (the acquisition unit), a total effective electric power calculation unit 5007 (the first calculation unit), a component base measuring unit 5008 (the measuring unit), and an integration unit 5006, by executing a predetermined adjustment power measuring process program.

The effective electric power acquisition unit 5001 acquires an effective electric power measured value P₁ at the connection point where the measurement equipment 50 is provided, from the sensor 504. The frequency acquisition unit 5003 acquires a frequency measured value f₁ at the connection point where the measurement equipment 50 is provided, from the sensor 504.

The total effective electric power calculation unit 5007 (the first calculation unit) calculates a total variation value ΔPₜₒₜₐₗ of the short-cycle and the long-cycle electric power demand of the entire electric power system or a total variation value ΔPₜₒₜₐₗ of the short-cycle and the long-cycle electric power supply, based on the frequency f₁, which is measured at the connection point, and the reference frequency set in the first power transmission and distribution network N1.

The component base measuring unit 5008 (the measuring unit) measures the adjustment power corresponding to each of the single or the plurality of classifications according to the speed of the response of the electric power demand or the electric power supply, based on the total variation value ΔPₜₒₜₐₗ of the electric power demand or the electric power supply. In the present embodiment, an example in which the component base measuring unit 5008 measures first adjustment power corresponding to a first classification indicating a slow response, second adjustment power corresponding to a second classification indicating a fast response, and third adjustment power indicating a response of speed between the first classification and the second classification, individually will be described. In another embodiment, there may be only one classification (for example, only any one of the first classification, the second classification, and the third classification), or may be four or more classifications. When the classification is divided into four or more, for example, the third classification may be further divided into two or more classifications.

The integration unit 5006 calculates an adjustment power integrated value for each of the plurality of classifications. In the present embodiment, the integration unit 5006 calculates each of a first adjustment power integrated value in which the first adjustment power is integrated, a second adjustment power integrated value in which the second adjustment power is integrated, and a third adjustment power integrated value in which the third adjustment power is integrated.

In the fifth embodiment, the short-cycle component of the adjustment power is calculated by using Equation (26), and the long-cycle component of the adjustment power is calculated by using Equation (44). In the case of the two divisions of a long cycle and a short cycle, the cycles are separated from each other, so that both cycles can be handled in the above way. However, when the number of divisions is increased, it is troublesome to change the calculation equations for each division. Therefore, in the present embodiment, for example, the calculation equations are unified as described below.

First, a method for calculating the effective electric power in the total effective electric power calculation unit 5007 according to the present embodiment will be described. In the fifth embodiment, the increment of the long-cycle effective electric power exchanged at adjustment power supply means, which includes the consumer C or the power generation company G, and the power transmission and distribution network for each time T, is calculated by using Equation (44). In the present embodiment, above Equation is rewritten as an increment of one time step as in following Equation (47). The total sum Σ is a total sum of the adjustment power supply means and is an increment of the total sum of the long-cycle effective electric powers when the time history of the frequency is f₁.

$$Δ {P}_{L F C} = - \left(\sum {K}_{p}\right) Δ {f}_{1} - \left(\sum \frac{{K}_{p}}{{T}_{I}}\right) \left({f}_{1} - {r}_{f}\right) \qquad \text{(47)}$$

Similarly, the increment of the total sum of the short-cycle effective electric powers of the entire system is represented by following Equation (48).

$$Δ {P}_{G F} = - \left(\sum \frac{1}{δ} \frac{{P}_{n}}{{f}_{n}}\right) Δ {f}_{1} \qquad \text{(48)}$$

As represented in Equation (49), the increment of the effective electric power of the entire system is a sum ΔPₜₒₜₐₗ of the short-cycle component ΔP_{GF} and the long-cycle component ΔP_{LFC} .

$$Δ {P}_{t o t a l} = Δ {P}_{G F} + Δ {P}_{L F C} \qquad \text{(49)}$$

The adjustment power of the adjustment power supply means is determined by using Equation (50) based on whether or not the increment ΔP₁ of the effective electric power is in the same direction with the ΔPₜₒₜₐₗ.

$$Δ {P}_{\text{R} t o t a l , 1} = s g n \left(Δ {P}_{t o t a l}\right) Δ {P}_{1} \qquad \text{(50)}$$

Next, a method of dividing the adjustment power according to the speed of the response by the component base measuring unit 5008 will be described. For example, a case where 3 divisions of a fast component (the second classification), an intermediate component (the third classification), and a slow component (the first classification) are made will be described. For example, the fast component has a response time constant of 10 seconds or less, the intermediate component has a response time constant of 10 to 300 seconds, and the slow component has a response time constant of 300 to 2700 seconds.

The fast component ΔP_{R1},ₐ of the adjustment power is calculated by using Equation (53) based on a fast component ΔPₜₒₜₐₗ,ₐ of the increment ΔPₜₒₜₐₗ of the total sum of the effective electric powers calculated by using Equation (51) and a fast component ΔP₁,ₐ of the increment ΔP₁ of the effective electric power calculated by using Equation (52). s is a Laplace operator, and 10s/(10s + 1) is an example of a transfer function for extracting a fast component. The transfer function performs numerical calculation by equivalent conversion to a digital filter such as a finite impulse response (FIR) filter or an infinite impulse response (IIR) filter. Of course, the digital filter may be directly specified. The same applies to a transfer function of the intermediate component or the slow component.

$$Δ {P}_{t o t a l , a} = \frac{10 s}{10 s + 1} Δ {P}_{t o t a l} \qquad \text{(51)}$$

$$Δ {P}_{1 , a} = \frac{10 s}{10 s + 1} Δ {P}_{1} \qquad \text{(52)}$$

$$Δ {P}_{\text{R1,} a} = s g n \left(Δ {P}_{t o t a l , a}\right) Δ {P}_{1 , a} \qquad \text{(53)}$$

The intermediate component ΔP_{R1}, _{b} of the adjustment power can be calculated by using Equation (56) based on an intermediate component ΔPₜₒₜₐₗ, _{b} of the increment ΔPₜₒₜₐₗ of the total sum of the effective electric powers calculated by using Equation (54) and an intermediate component ΔP₁, _{b} of the increment ΔP₁ of the effective electric power calculated by using Equation (55). The process in Equation (54) is for illustrating an example of a process of a band-passing filter (band pass filter) that selectively passes the intermediate component, and the method of the process is not limited thereto.

$$Δ {P}_{t o t a l , b} = \frac{300 s}{300 s + 1} \left(Δ {P}_{t o t a l} - Δ {P}_{t o t a l , a}\right) \qquad \text{(54)}$$

$$Δ {P}_{1 , b} = \frac{300 s}{300 s + 1} \left(Δ {P}_{1} - Δ {P}_{1 , a}\right) \qquad \text{(55)}$$

$$Δ {P}_{\text{R1,} b} = s g n \left(Δ {P}_{t o t a l , b}\right) Δ {P}_{1 , b} \qquad \text{(56)}$$

The slow component ΔP_{R1},_{c} of the adjustment power is calculated by using Equation (59) based on a slow component ΔPₜₒₜₐₗ,_{c} of the increment ΔPₜₒₜₐₗ of the total sum of the effective electric powers calculated by using Equation (57) and a slow component ΔP₁,_{b} of the increment ΔP₁ of the effective electric power calculated by using Equation (58).

$$Δ {P}_{t o t a l , c} = \frac{2700 s}{2700 s + 1} \left(Δ {P}_{t o t a l} - Δ {P}_{t o t a l , a}\right) \qquad \text{(57)}$$

$$Δ {P}_{1 , c} = \frac{2700 s}{2700 s + 1} \left(Δ {P}_{1} - Δ {P}_{1 , a}\right) \qquad \text{(58)}$$

$$Δ {P}_{\text{R1,} c} = s g n \left(Δ {P}_{t o t a l , c}\right) Δ {P}_{1 , c} \qquad \text{(59)}$$

Next, in the integration unit 5006, the adjustment power of the power source 21 in the unit period is calculated by dividing components into the fast component, the intermediate component, and the slow component by using Equation (60).

$${W}_{\left[{t}_{i n i} , {t}_{t e r}\right] , 1 , j} = {\sum }_{t = {t}_{i n i} , {t}_{i n i} + T , ⋯ , {t}_{t e r}} Δ {P}_{\text{R1,} j} Δ t j ∈ \left\{a , b , c\right\} \qquad \text{(60)}$$

### (Effects of Action)

As described above, the adjustment power measuring device (measurement equipment 50) according to the present embodiment includes the total effective electric power calculation unit 5007 (the first calculation unit) that calculates the total value of the long-cycle and the short-cycle effective electric power of the entire electric power system based on the frequency measured at the connection point and the reference value of the frequency set in the first power transmission and distribution network N1, the component base measuring unit 5008 (the measuring unit) that measures the adjustment power corresponding to each of the plurality of classifications according to the speed of the response of the electric power demand or the electric power supply based on the total value of the effective electric power, and the integration unit 5006 that calculates the adjustment power integrated value for each of the plurality of classifications.

In this way, it is possible to measure the adjustment power by dividing the components for each speed of the response of the electric power supply and demand. Accordingly, for example, the compensation for the adjustment power can be more appropriately calculated by changing the unit price of the adjustment power according to the speed of the response.

### Seventh Embodiment

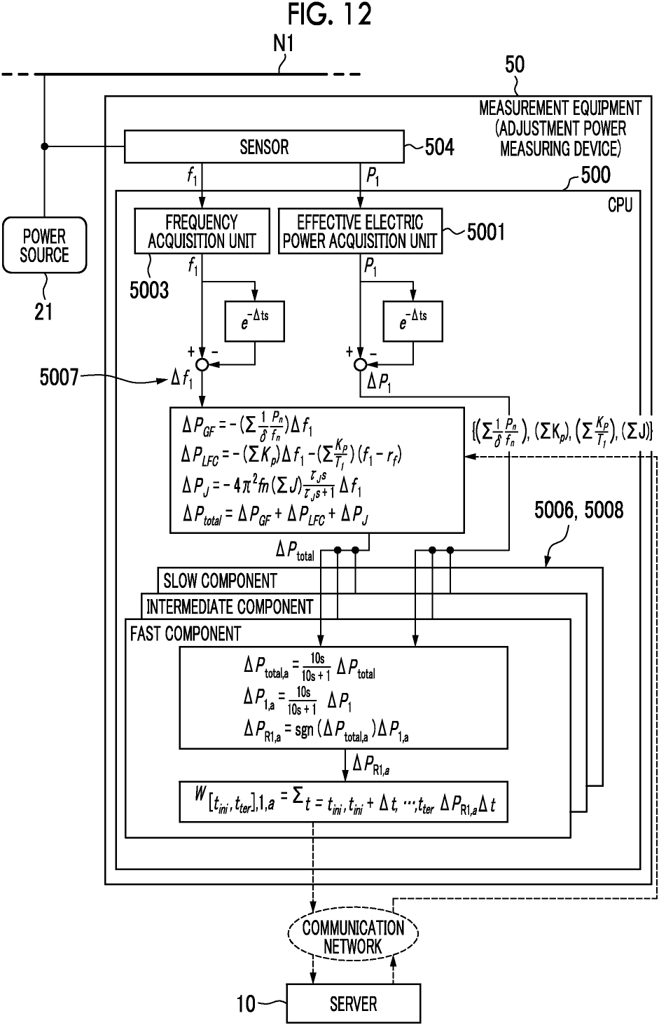

Next, an adjustment power measuring system according to a seventh embodiment of the present disclosure will be described with reference to FIG. 12.

The same reference numerals are given to the components common to those of the first to sixth embodiments, and a detailed description thereof will be omitted.

### (Functional Configuration of Measurement Equipment)

FIG. 12 is a block diagram illustrating a functional configuration of the measurement equipment according to the seventh embodiment of the present disclosure.

As illustrated in FIG. 12, in the measurement equipment 50 according to the present embodiment, the total effective electric power calculation unit 5007 (the first calculation unit) calculates the total variation value ΔPₜₒₜₐₗ of the long-cycle and the short-cycle electric power demand of the entire electric power system or the total variation value ΔPₜₒₜₐₗ of the long-cycle and the short-cycle electric power supply by further using the inertial energy of a rotating body included in the adjustment power providing means.

Recently, attention has been paid to the inertia included in a turbine device 211 or a generator 212 of the power source 21 in the supply and demand adjustment of the electric power. The rotating body such as the generator 212 or the turbine device 211 has inertial energy proportional to the square of the rotation speed. Since these rotation speeds are synchronized with the frequency of the system, when the frequency of the system is increased due to the supply and demand variation, the rotating body implicitly deprives the system of the equivalent of inertial energy. The larger the rotational inertia, the more inertial energy is deprived, so that the supply and demand variation is offset and the resulting frequency variation becomes smaller. Therefore, it is desirable that the inertia is large from the viewpoint of the supply and demand adjustment.

In the present embodiment, the exchange of the inertial energy can also be measured. This will be described below. Equation (61) represents the inertial energy of the entire system with the electric angular velocity ω.

$${W}_{I} = \frac{{ω}^{2}}{2} \sum J \qquad \text{(61)}$$

When the inertial energy is time-differentiated around the reference angular velocity ωₙ, the inertia becomes the effective electric power P_{J} supplied to the electric power system. Since the amount of the decrease in the inertial energy is supplied to the system, the time change rate of the inertial energy is given a negative sign.

$$\begin{matrix}{P}_{J} = - {\dot{W}}_{J} \\ = - {ω}_{n} \dot{ω} \left(\sum J\right) \\ = - 4 {π}^{2} {f}_{n} \dot{f} \left(\sum J\right)\end{matrix} \qquad \text{(62)}$$

The time differentiation of the frequency is required to calculate P_{J}. The differentiation can be calculated in principle by the time difference, but in order to avoid the influence of an error of an observed value of the frequency f, the differentiation is replaced with a pseudo-differentiation and represented in Equation (63). τ_{J} is a time constant of pseudo-differentiation, and is set to a value such as 0.2 seconds.

$${P}_{J} = - 4 {π}^{2} {f}_{n} \left(\sum J\right) ⋅ \frac{{τ}_{J} s}{{τ}_{l} s + 1} f \qquad \text{(63)}$$

As in the sixth embodiment, Equation (64) is obtained by time-difference of Equation (63) by Δt.

$$Δ {P}_{J} = - 4 {π}^{2} {f}_{n} \left(\sum J\right) ⋅ \frac{{τ}_{J} s}{{τ}_{J} s + 1} Δ f \qquad \text{(64)}$$

In the sixth embodiment, the increment ΔPₜₒₜₐₗ of the effective electric power of the system is calculated by using Equation (49) as the sum of ΔP_{GF} and ΔP_{LFC}. In the present embodiment, the increment ΔPₜₒₜₐₗ of the effective electric power of the system is evaluated by using Equation (65) in consideration of the effective electric power ΔP_{J} generated by the inertia.

$$Δ {P}_{t o t a l} = Δ {P}_{G F} + Δ {P}_{L F C} + Δ {P}_{I} \qquad \text{(65)}$$

Subsequent processes (the processes of the component base measuring unit 5008 and the integration unit 5006) are the same as those of in the sixth embodiment.

A value of the total sum of inertia ΣJ of the electric power system may be a predetermined fixed value and may be obtained from the server 10 or the like via a communication network, with a value changed in accordance with the season, the time, the area, or the like, as illustrated in FIG. 12. Similar to ΣJ, the following value may also be obtained from the server 10 or the like via the communication network.

$$\left\{\left(\sum \frac{1}{δ} \frac{{P}_{n}}{{f}_{n}}\right) , \left(\sum {K}_{p}\right) , \left(\sum \frac{{K}_{P}}{{T}_{I}}\right) , \left(\sum J\right)\right\} \qquad \text{(66)}$$

### (Effects of Action)

As described above, in the adjustment power measuring device (the measurement equipment 50) according to the present embodiment, the total effective electric power calculation unit 5007 (the first calculation unit) calculates the total variation value ΔPₜₒₜₐₗ of the long-cycle electric power demand of the entire electric power system or the total variation value ΔPₜₒₜₐₗ of the short-cycle electric power supply in addition to the effective electric power generated by the inertia of the rotating body included in the adjustment power providing means.

In this way, it is possible to measure more precise adjustment power in consideration of the effective electric power generated by the inertia of the rotating body of the adjustment power providing means.

The total effective electric power calculation unit 5007 (the first calculation unit) may calculate the effective electric power generated by the inertia of the rotating body of the adjustment power providing means based on a parameter acquired from the server 10 and indicating the total sum of the inertia of the electric power system according to the date and time or the area.

In this way, even when the server 10 updates the parameter, each of the plurality of adjustment power measuring devices can always calculate the effective electric power by using the latest parameter. The server 10 may change the parameters for each of a period of time, time, and an area where the power transmission and distribution network is provided. As a result, the effective electric power, which is generated by the inertia, can be calculated more accurately.

### Eighth Embodiment

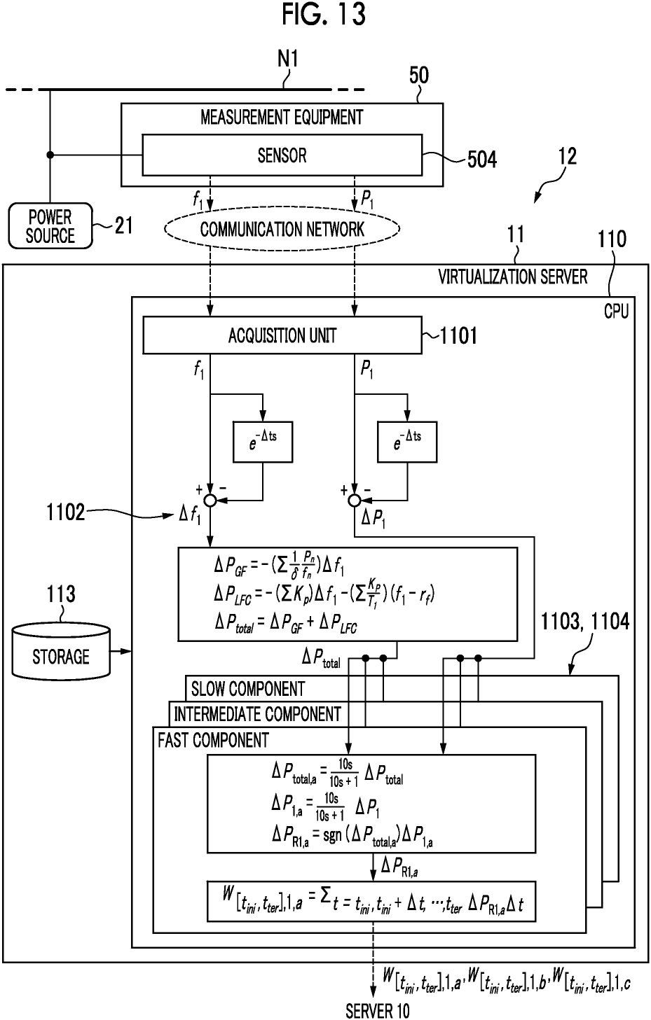

Next, an adjustment power measuring system according to an eighth embodiment of the present disclosure will be described with reference to FIG. 13.

The same reference numerals are given to the components common to those of the first to seventh embodiments, and a detailed description thereof will be omitted.

### (Functional Configuration of Measurement Equipment and Virtualization Server)

FIG. 13 is a block diagram illustrating a functional configuration of measurement equipment and a virtualization server according to the eighth embodiment of the present disclosure.

In the sixth embodiment, as illustrated in FIG. 11, the measurement equipment 50, which is disposed close to the power source 21, is used as the adjustment power measuring device. However, as illustrated in FIG. 13, for example, the function of the CPU 500 of the measurement equipment 50 may be implemented in the virtualization server 11 disposed at a remote location of the power source 21. That is, the adjustment power measuring system 1 according to the present embodiment includes the measurement equipment 50 and the virtualized adjustment power measuring device 12, which includes the virtualization server 11. At this time, the frequency f₁ and the effective electric power P₁ output by the sensor 504 of the measurement equipment 50 are transmitted to the virtualization server 11 through the communication network, and the CPU 110 of the virtualization server 11 calculates the adjustment power of the adjustment power providing means.

Specifically, the CPU 110 of the virtualization server 11 according to the present embodiment functions as an acquisition unit 1101, a total effective electric power calculation unit 1102 (the first calculation unit), a component base measuring unit 1103 (the measuring unit), and an integration unit 1104 by executing a predetermined adjustment power measuring process program. The functions of the total effective electric power calculation unit 1102, the component base measuring unit 1103, and the integration unit 1104 are the same as the functions of the total effective electric power calculation unit 5007, the component base measuring unit 5008, and the integration unit 5006 according to the sixth embodiment or the seventh embodiment, respectively. A plurality of adjustment power measuring process programs respectively corresponding to a plurality of power sources or loads are stored in a storage 113 of the virtualization server 11. The CPU 110 executes each adjustment power measuring process program sequentially or simultaneously and measures the adjustment power of each of the plurality of power sources or loads. The adjustment power for each power source or load calculated by the virtualization server 11 is aggregated in the server 10, and the compensation thereof is settled.

### (Effects of Action)

As described above, the adjustment power measuring device according to the present embodiment includes the measurement equipment 50 and the virtualization server 11 connected to the measurement equipment 50 in a communicable manner. The virtualization server 11 includes the total effective electric power calculation unit 1102 (the first calculation unit) that calculates the total value of the long-cycle and the short-cycle effective electric power of the entire electric power system based on the frequency measured at the connection point and the reference value of the frequency set in the first power transmission and distribution network N1 and the component base measuring unit 1103 (the measuring unit) that measures the adjustment power corresponding to each of the plurality of classifications according to the speed of the response of the electric power demand or the electric power supply based on the total value of the effective electric power.

In this way, only by connecting the virtualization server 11 to the measurement equipment in the related art, it is possible to measure the adjustment power of each adjustment power providing means by dividing components for each speed of the response.

### Ninth Embodiment

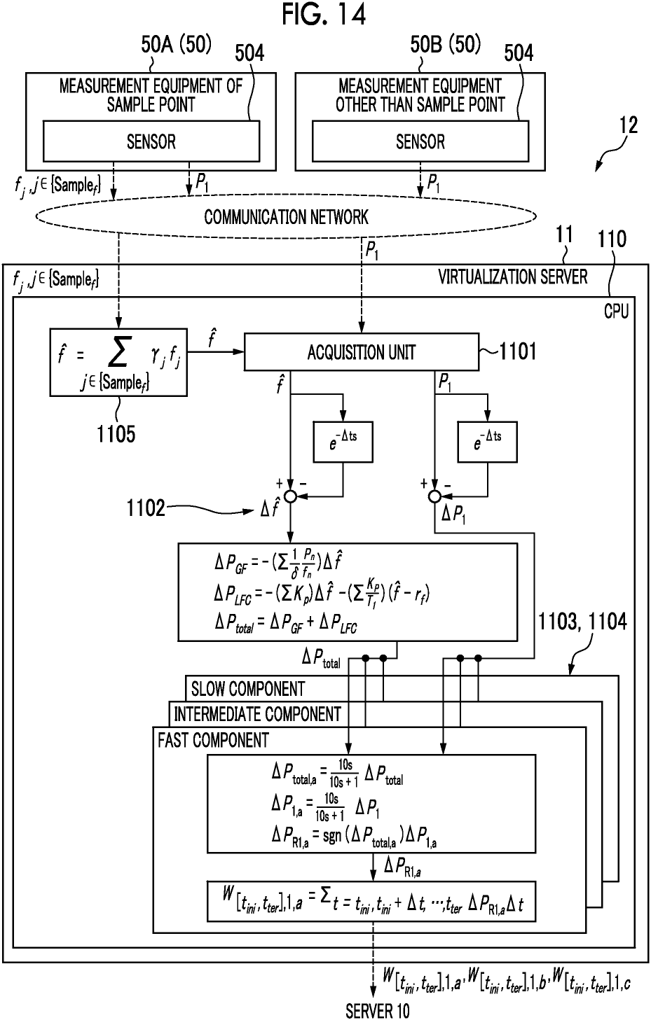

Next, an adjustment power measuring system according to a ninth embodiment of the present disclosure will be described with reference to FIG. 14.

The same reference numerals are given to the components common to those of the first to eighth embodiments, and a detailed description thereof will be omitted.

### (Functional Configuration of Measurement Equipment and Virtualization Server)

FIG. 14 is a block diagram illustrating a functional configuration of measurement equipment and a virtualization server according to the ninth embodiment of the present disclosure.

In the eighth embodiment, the measurement equipment 50 of the virtualized adjustment power measuring device 12 needs to transmit two measured values of the frequency f of one power source or load, and the effective electric power P to the virtualization server 11. However, when the virtualization server 11 attempts to virtualize the adjustment power measuring device of the power source or the load for the entire area managed by the system operator, the amount of communication between the measurement equipment 50 and the virtualization server 11 poses a problem.

Therefore, the measurement equipment 50 according to the present embodiment transmits only the effective electric power P from each power source or load to reduce the amount of communication. The frequency is replaced with a representative frequency.

The representative frequency will be described. For the representative frequency f^, the frequency f is acquired from the power source or load, which is assumed as a sample point, for example, as in Equation (67), the representative frequency f^ is determined from a weighted average of the sample points. Y is a load coefficient. A value of Y can be determined by a method of a least absolute shrinkage and selection operator (LASSO) regression.

$$\hat{f} = {\sum }_{j ∈ \left\{{\text{Sample}}_{f}\right\}} {γ}_{i} {f}_{i} \qquad \text{(67)}$$

A set of the sample points is referred to as “Sample_{f}”. The “Sample_{f}” may be the same as that in Equation (12), that is, may be “Sample” or may be different from “Sample”. It is desirable to reduce the number of sample points to be smaller than the total number of power sources or loads in the area managed by the system operator in order to reduce the amount of communication. For example, when it is known that a frequency of a certain location (for example, Kumamoto City Hall) behaves the same as the representative frequency of a certain area (for example, Kyushu area), only Kumamoto City Hall may be selected as an element of “Sample_{f}”. In this way, the representative frequency can be determined with a very small number of samples, and the communication load can be reduced.

As illustrated in FIG. 14, measurement equipment 50A of a power source or a load, which is an element of the sample point, transmits the frequency f, which is measured by the sensor 504, to the virtualization server 11 via the communication network. The CPU 110 of the virtualization server 11 further functions as a representative frequency determination unit 1105 that inputs the frequency of the sample point and outputs the representative frequency by executing the predetermined representative frequency determining process program. The representative frequency determination unit 1105 obtains the representative frequency f^ of the area to which the sample point belongs, based on the frequency f of the sample point. A measurement equipment 50B of a power source or a load other than the sample point transmits only the measured value P₁ of the effective electric power to the virtualization server 11 to reduce the amount of communication.

The total effective electric power calculation unit 1102 uses the representative frequency f^ instead of the frequency f to calculate the total variation value ΔPₜₒₜₐₗ of the long-cycle and the short-cycle electric power demand or the electric power supply of the entire electric power system. The functions of the component base measuring unit 1103 and the integration unit 1104 are the same as those in the eighth embodiment.

### (Effects of Action)

As described above, the virtualization server 11 according to the present embodiment further includes the representative frequency determination unit 115 that inputs the frequency of the connection point, among the plurality of connection points, that is a sample point and outputs the representative frequency f^ of the area that includes the sample point.

In this way, since the frequency may be acquired only from the measurement equipment 50A of the sample point among the plurality of measurement equipment 50, the amount of communication between the measurement equipment 50 and the virtualization server 11 can be reduced.

### Tenth Embodiment

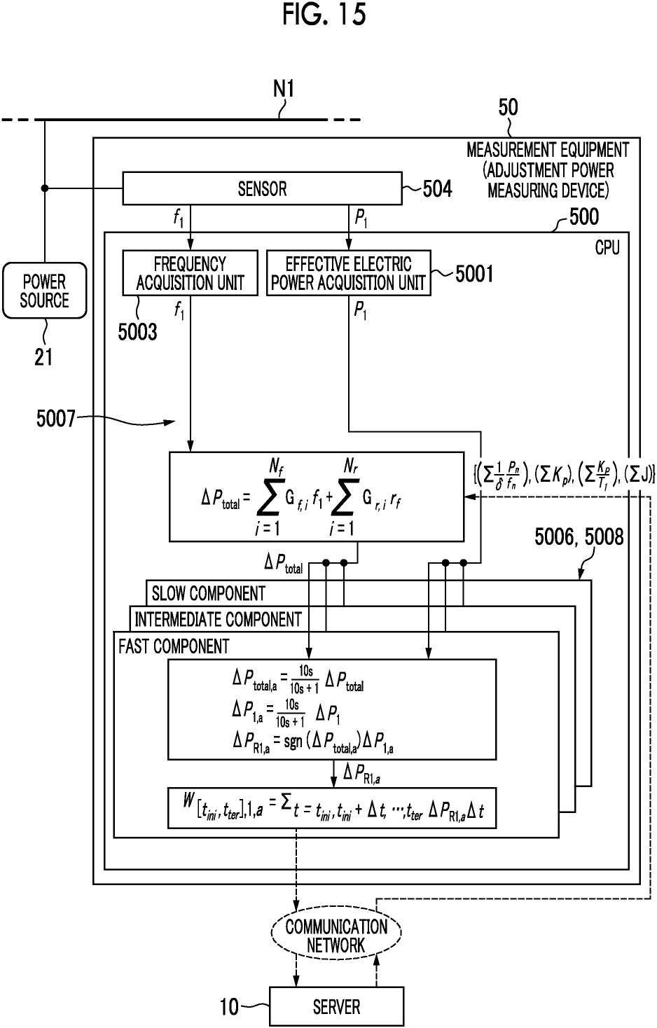

Next, an adjustment power measuring system according to a tenth embodiment of the present disclosure will be described with reference to FIG. 15.

The same reference numerals are given to the components common to those of the first to ninth embodiments, and a detailed description thereof will be omitted.

### (Functional Configuration of Measurement Equipment)

FIG. 15 is a block diagram illustrating a functional configuration of the measurement equipment according to the tenth embodiment of the present disclosure.

The measurement equipment 50 illustrated in FIG. 15 is a summary of the fourth, fifth, and seventh embodiments.

In the fourth embodiment, the adjustment power is calculated from ΔP₁ and Δf₁.

In the fifth embodiment, the adjustment power is calculated from ΔP₁, Δf₁, f₁, and the reference frequency rf.

In the seventh embodiment, the adjustment power is calculated from the pseudo-differentiation values of ΔP₁, Δfₜ, f₁, rf, and Δf₁.

Here, ΔP₁ is a value obtained by multiplying P₁ by a transfer function representing a time difference. Similarly, Δf₁ is a value obtained by multiplying f₁ by the transfer function representing the time difference.

The measurement equipment 50 (the adjustment power measuring device) according to the present embodiment is a device that inputs P₁, f₁, and rf and produces the adjustment power based on a sum of the loads weighted by the transfer function.

For example, in the measurement equipment 50 according to the present embodiment, the total effective electric power calculation unit 5007 calculates a total variation value of the long-cycle and the short-cycle electric power demand or a total variation value of the long-cycle and the short-cycle electric power supply of the entire electric power system as follows instead of the process in the seventh embodiment (FIG. 12).

When a transfer function serving as the weight of the frequency is represented by G_{f} (a first transfer function) and a transfer function serving as the weight of the reference value of the frequency is represented by Gᵣ (a second transfer function), Equation (65) can be represented as Equation (68), for example. Nf and Nr are the number of transfer functions that serve as weights.

$$Δ {P}_{t o t a l} = {\sum }_{i = 1}^{{N}_{f}} {G}_{f , i} {f}_{1} + {\sum }_{i = 1}^{{N}_{r}} {G}_{r , i} {r}_{f} \qquad \text{(68)}$$

Specifically, the transfer function may be set as in Equation (69) with N_{f} = 3 and Nᵣ = 1.

$$\left(\begin{matrix}{G}_{f , 1} = - \left(\left(\sum \frac{1}{δ} \frac{{P}_{n}}{{f}_{n}}\right) + \left(\sum {K}_{p}\right)\right) \left(1 - {e}^{- Δ t s}\right) \\ {G}_{f , 2} = - \left(\sum \frac{{K}_{P}}{{T}_{I}}\right) \\ {G}_{f , 3} = - 4 {π}^{2} {f}_{n} \left(\sum J\right) \frac{{τ}_{J} s}{{τ}_{J} s + 1} \left(1 - {e}^{- Δ t s}\right) \\ {G}_{r , 1} = \left(\sum \frac{{K}_{P}}{{T}_{I}}\right)\end{matrix}\right\} \qquad \text{(69)}$$

Since the reference frequency r_{f} is substantially a fixed value of 50 Hz or 60 Hz, the reference frequency r_{f} may be handled as a fixed value without being received using the communication network.

The functions of the component base measuring unit 5008 and the integration unit 5006 are the same as those in the seventh embodiment.

### (Effects of Action)

As described above, the measurement equipment 50 (the adjustment power measuring device) according to the present embodiment calculates the total variation value ΔPₜₒₜₐₗ of the short-cycle and the long-cycle electric power demand or the total variation value ΔPₜₒₜₐₗ of the short-cycle and the long-cycle electric power supply of the entire electric power system by further using the first transfer function indicating the weight of the frequency and the second transfer function indicating the weight of the frequency reference value, in addition to the frequency f₁ of the connection point and the frequency reference value r_{f}.

In this way, it is possible to shorten the processing time required for the calculation of the adjustment power in the measurement equipment 50.

In each of the above-described embodiments, various processing procedures of the above-described adjustment power measuring device (the server 10, the measurement equipment 50) are stored in a computer-readable recording medium in a form of a program, and the above-mentioned various processes are performed by the computer (the CPU 100, the CPU 500) reading and executing this program. Examples of the computer-readable recording medium include a magnetic disk, a magneto-optical disk, a CD-ROM, a DVD-ROM, a semiconductor memory, and the like. The computer program may be distributed to a computer via a communication line, and the computer receiving the distribution may execute the program.

The program may be for implementing a part of the above-mentioned functions. Further, the program may be a file, a so-called difference file (difference program), that can implement the above-mentioned functions in combination with a program already recorded in a computer system.

Although the embodiments of the present disclosure have been described in detail above, the present disclosure is not limited to these as long as it does not deviate from the technical idea of the present disclosure, and some design changes are possible.

For example, in the first to third embodiments, the aspect in which the server 10 of the system operator T functions as the adjustment power measuring device has been described, but the present disclosure is not limited thereto. In other embodiments, when the measurement equipment 50 can aggregate the electric power demand or the electric power supply of each power transmission and distribution network N from the server 10 of each system operator T, the measurement equipment 50 may function as the adjustment power measuring device by incorporating each functional unit of the CPU 100 of the server 10 into the CPU 500 of the measurement equipment 50.

### Additional Notes

The adjustment power measuring device, the adjustment power measuring system, the adjustment power measuring method, and the program according to the above-described embodiments are ascertained as follows, for example.

According to a first aspect of the present disclosure, an adjustment power measuring device is an adjustment power measuring device that measures adjustment power of an electric power supply and demand balance provided to a first power transmission and distribution network that is a management target among a plurality of power transmission and distribution networks included in an electric power system, the adjustment power measuring device includes: an acquisition unit that acquires effective electric power exchanged at a connection point with adjustment power providing means capable of providing adjustment power to the first power transmission and distribution network; a first calculation unit that calculates electric power demand or electric power supply of an entire electric power system including the first power transmission and distribution network; and a measuring unit that measures first adjustment power provided to the first power transmission and distribution network by the adjustment power providing means, based on the effective electric power and the electric power demand or the electric power supply of the electric power system.

In this way, the adjustment power measuring device can appropriately measure how the effective electric power of the adjustment power providing means has contributed to the long-cycle supply and demand variation in the electric power. Therefore, the adjustment power measuring device can accurately measure the sustainable adjustment power in a long cycle by the adjustment power providing means.

According to a second aspect of the present disclosure, in the adjustment power measuring device according to the first aspect, the measuring unit calculates an adjustment power coefficient representing an influence degree of variation in the effective electric power with respect to variation in the electric power demand or the electric power supply of the electric power system, based on the effective electric power and the electric power demand or the electric power supply of the electric power system, and measures the first adjustment power based on the calculated adjustment power coefficient and a variation amount of the electric power demand or the electric power supply of the electric power system.

In this way, the adjustment power measuring device can accurately measure the adjustment power.

According to a third aspect of the present disclosure, in the adjustment power measuring device according to the first aspect, the measuring unit uses a sign function to measure temporal change in the effective electric power as positive or negative adjustment power in accordance with a direction of temporal change in the electric power demand or the electric power supply of the electric power system.

In this way, the adjustment power measuring device can reduce the load of calculation. As a result, for example, the adjustment power can be easily calculated for all the consumer, the power generation company, and the like including the household in the area (the first power transmission and distribution network), which are management targets of the adjustment power measuring device.

According to a fourth aspect of the present disclosure, the adjustment power measuring device according to any one of the first to third aspects further includes a planning unit that sets a planned value of electric power, which is demanded or supplied by the adjustment power providing means of the first power transmission and distribution network, based on a predicted value of the electric power demand or the electric power supply of the electric power system. The measuring unit measures the first adjustment power by using a value obtained by subtracting the planned value from the effective electric power, for the adjustment power providing means performing demand or supply of electric power according to the planned value.

In this way, when the adjustment power providing means exerts the adjustment power with respect to the supply and demand variation in the electric power system in addition to the planned value, the adjustment power measuring device can appropriately measure the adjustment power.

According to a fifth aspect of the present disclosure, the adjustment power measuring device according to any one of the first to fourth aspects further includes an integration unit that calculates an adjustment power integrated value obtained by integrating the first adjustment power, which is measured by the measuring unit, in a predetermined unit period.

In this way, the adjustment power measuring device can easily know, for example, the daily adjustment power of each of the adjustment power providing means.

According to a sixth aspect of the present disclosure, in the adjustment power measuring device according to the fifth aspect, the acquisition unit further acquires second adjustment power, which is adjustment power that responds to supply and demand variation having a cycle shorter than that of the first adjustment power and which is based on a frequency at the connection point and the effective electric power exchanged at the connection point, and the integration unit calculates the adjustment power integrated value based on the first adjustment power measured by the measuring unit and the second adjustment power acquired by the acquisition unit.

In this way, the adjustment power measuring device can evaluate both the short-cycle component and the long-cycle component of the adjustment power of each of the adjustment power providing means.

According to a seventh aspect of the present disclosure, the adjustment power measuring device according to any one of the first to sixth aspects further includes a second calculation unit that calculates electric power demand or electric power supply of the first power transmission and distribution network based on the effective electric power of a plurality of adjustment power providing means acquired by the acquisition unit. The first calculation unit calculates the electric power demand or the electric power supply of the entire electric power system by calculating a total of the electric power demand or the electric power supply of the first power transmission and distribution network, which is calculated by the second calculation unit, and electric power demand or electric power supply of a second power transmission and distribution network, which is acquired from an adjustment power measuring device of a system operator who manages the second power transmission and distribution network included in the electric power system.

In this way, the adjustment power measuring device can know the electric power demand or the electric power supply of the entire electric power system including both the first power transmission and distribution network, which is a management target, and the second power transmission and distribution network, which is a management target of another system operator.

According to an eighth aspect of the present disclosure, in the adjustment power measuring device according to any one of the first to sixth aspects, the acquisition unit further acquires a frequency at the connection point, and the first calculation unit calculates the electric power demand or the electric power supply of the entire electric power system based on the frequency and a reference value of a frequency set in the first power transmission and distribution network.

In this way, by calculating and aggregating the electric power demand or the electric power supply of the power transmission and distribution network in which each of the plurality of system operators are management targets, the process of calculating the electric power demand or the electric power supply of the entire electric power system becomes unnecessary. Therefore, the adjustment power measuring device can reduce the calculation load on the server of each system operator. Since communication between the servers of each system operator for each predetermined time is not required, the traffic between the servers can be significantly reduced.

According to a ninth aspect of the present disclosure, in the adjustment power measuring device according to the fifth aspect, the acquisition unit further acquires a frequency at the connection point, the first calculation unit calculates a total value of short-cycle and long-cycle electric power demand or a total value of short-cycle and long-cycle electric power supply of the entire electric power system, based on the frequency and a reference value of a frequency set in the first power transmission and distribution network, the measuring unit measures adjustment power corresponding to a single or a plurality of classifications in accordance with a speed of response of the electric power demand or the electric power supply, based on the total value of the electric power demand or the total value of the electric power supply, and the integration unit calculates the adjustment power integrated value for each of the single or the plurality of classifications.

In this way, it is possible to measure the adjustment power by dividing the components for each speed of the response of the electric power supply and demand. Accordingly, for example, the compensation for the adjustment power can be more appropriately calculated by changing the unit price of the adjustment power according to the speed of the response.

According to a tenth aspect of the present disclosure, in the adjustment power measuring device according to the ninth aspect, the first calculation unit calculates a total value of the long-cycle electric power demand or a total value of the short-cycle electric power supply by further adding effective electric power generated by inertia of a rotating body included in the adjustment power providing means.

In this way, it is possible to measure more precise adjustment power in consideration of the effective electric power generated by the inertia of the rotating body of the adjustment power providing means.

According to an eleventh aspect of the present disclosure, in the adjustment power measuring device according to the tenth aspect, the first calculation unit calculates the effective electric power generated by the inertia of the rotating body based on a parameter indicating a total sum of inertia of the electric power system acquired from an external server.

In this way, even when the server updates the parameter, each of the plurality of adjustment power measuring devices can always calculate the effective electric power by using the latest parameter.

According to a twelfth aspect of the present disclosure, in the adjustment power measuring device according to the ninth aspect, the first calculation unit calculates the total value of the short-cycle and the long-cycle electric power demand or the total value of the short-cycle and the long-cycle electric power supply of the entire electric power system by further using a first transfer function indicating a weight of the frequency and a second transfer function indicating a weight of the reference value of the frequency.

In this way, it is possible to shorten the processing time required for the calculation of the adjustment power in the adjustment power measuring device.

According to a thirteenth aspect of the present disclosure, an adjustment power measuring system is an adjustment power measuring system that measures adjustment power of an electric power supply and demand balance provided to a first power transmission and distribution network that is a management target among a plurality of power transmission and distribution networks included in an electric power system, the adjustment power measuring system includes: an acquisition unit that acquires effective electric power exchanged at a connection point with adjustment power providing means capable of providing adjustment power to the first power transmission and distribution network; a first calculation unit that calculates electric power demand or electric power supply of an entire electric power system including the first power transmission and distribution network; and a measuring unit that measures first adjustment power provided to the first power transmission and distribution network by the adjustment power providing means, based on the effective electric power and the electric power demand or the electric power supply of the electric power system.

In this way, the adjustment power measuring system can accurately measure the long-cycle and sustainable adjustment power by the adjustment power providing means.

According to a fourteenth aspect of the present disclosure, in the adjustment power measuring system according to the thirteenth aspect, the acquisition unit further acquires a frequency at the connection point, and the measuring unit includes a first measuring unit that measures the first adjustment power and a second measuring unit that measures second adjustment power responding to supply and demand variation having a cycle shorter than that of the first adjustment power based on the effective electric power and the frequency.

In this way, the adjustment power measuring system can evaluate both the short-cycle component and the long-cycle component of the adjustment power of each of the adjustment power providing means.

According to a fifteenth aspect of the present disclosure, in the adjustment power measuring system according to the thirteenth aspect, the acquisition unit further acquires a frequency at the connection point, the first calculation unit calculates a total value of short-cycle and long-cycle electric power demand or a total value of short-cycle and long-cycle electric power supply of the entire electric power system, based on the frequency and a reference value of a frequency set in the first power transmission and distribution network, and the measuring unit measures adjustment power corresponding to a single or a plurality of classifications in accordance with a speed of response of the electric power demand or the electric power supply, based on the total value of the electric power demand or the total value of the electric power supply.

In this way, it is possible to measure the adjustment power by dividing the components for each speed of the response of the electric power supply and demand. Accordingly, for example, the compensation for the adjustment power can be more appropriately calculated by changing the unit price of the adjustment power according to the speed of the response.

According to a sixteenth aspect of the present disclosure, the adjustment power measuring system according to the fifteenth aspect further includes a representative frequency determination unit that inputs a frequency of a connection point serving as a sample point among a plurality of the connection points and outputs a representative frequency of an area including the sample point, in which the acquisition unit acquires the representative frequency as the frequency at the connection point.

In this way, it is only necessary to acquire the frequency from only the connection point serving as the sample point among the plurality of connection points, and thus it is possible to reduce the amount of communication required for frequency transmission.

According to an seventeenth aspect of the present disclosure, an adjustment power measuring method is an adjustment power measuring method of measuring adjustment power of an electric power supply and demand balance provided to a first power transmission and distribution network that is a management target among a plurality of power transmission and distribution networks included in an electric power system, the adjustment power measuring method includes: a step of acquiring effective electric power exchanged at a connection point with adjustment power providing means capable of providing adjustment power to the first power transmission and distribution network; a step of calculating electric power demand or electric power supply of an entire electric power system including the first power transmission and distribution network; and a step of measuring first adjustment power provided to the first power transmission and distribution network by the adjustment power providing means, based on the effective electric power and the electric power demand or the electric power supply of the electric power system.

According to an eighteenth aspect of the present disclosure, a program causes a computer of an adjustment power measuring device that measures adjustment power of an electric power supply and demand balance provided to a first power transmission and distribution network that is a management target among a plurality of power transmission and distribution networks included in an electric power system, to execute: a step of acquiring effective electric power exchanged at a connection point with adjustment power providing means capable of providing adjustment power to the first power transmission and distribution network; a step of calculating electric power demand or electric power supply of an entire electric power system including the first power transmission and distribution network; and a step of measuring first adjustment power provided to the first power transmission and distribution network by the adjustment power providing means, based on the effective electric power and the electric power demand or the electric power supply of the electric power system.

### Industrial Applicability

According to an adjustment power measuring device, an adjustment power measuring system, an adjustment power measuring method, and a program of the present disclosure, it is possible to accurately measure adjustment power for compensating for long-cycle supply and demand variation in electric power.

### REFERENCE SIGNS LIST

1: Adjustment power measuring system
10: Server (adjustment power measuring device)
100: CPU
1001: Acquisition unit
1002: First calculation unit
1003: Second calculation unit
1004: Measuring unit (first measuring unit)
1005: Integration unit
1006: Planning unit
1007: Settlement unit
101: Memory
102: Communication interface
103: Storage
11: Virtualization server
110: CPU
1101: Acquisition unit
1102: Total effective electric power calculation unit (first calculation unit)
1103: Component base measuring unit (measuring unit)
1104: Integration unit
113: Storage
12: Adjustment power measuring device
21, 22, 23: Power source
210: Control unit
211: Turbine device
212: Generator
50: Measurement equipment (adjustment power measuring device)
500: CPU
5001: Effective electric power acquisition unit (acquisition unit)
5002: Short-cycle component measuring unit (second measuring unit)
5003: Frequency acquisition unit (acquisition unit)
5004: LFC output calculation unit (first calculation unit)
5005: Long-cycle component measuring unit (first measuring unit)
5006: Integration unit
5007: Total effective electric power calculation unit (first calculation unit)
5008: Component base measuring unit (measuring unit)
501: Memory
502: Communication interface
503: Storage
504: Sensor

1. An adjustment power measuring device that measures adjustment power of an electric power supply and demand balance provided to a first power transmission and distribution network that is a management target among a plurality of power transmission and distribution networks included in an electric power system, the adjustment power measuring device comprising:
an acquisition unit that acquires effective electric power exchanged at a connection point with adjustment power providing means capable of providing adjustment power to the first power transmission and distribution network;
a first calculation unit that calculates electric power demand or electric power supply of an entire electric power system including the first power transmission and distribution network; and
a measuring unit that measures first adjustment power provided to the first power transmission and distribution network by the adjustment power providing means, based on the effective electric power and the electric power demand or the electric power supply of the electric power system.

2. The adjustment power measuring device according to claim 1, wherein
the measuring unit
calculates an adjustment power coefficient representing an influence degree of variation in the effective electric power with respect to variation in the electric power demand or the electric power supply of the electric power system, based on the effective electric power and the electric power demand or the electric power supply of the electric power system, and
measures the first adjustment power based on the calculated adjustment power coefficient and a variation amount of the electric power demand or the electric power supply of the electric power system.

3. The adjustment power measuring device according to claim 1, wherein
the measuring unit uses a sign function to measure temporal change in the effective electric power as positive or negative adjustment power in accordance with a direction of temporal change in the electric power demand or the electric power supply of the electric power system.

4. The adjustment power measuring device according to claim 1, further comprising:
a planning unit that sets a planned value of electric power, which is demanded or supplied by the adjustment power providing means of the first power transmission and distribution network, based on a predicted value of the electric power demand or the electric power supply of the electric power system, wherein
the measuring unit measures the first adjustment power by using a value obtained by subtracting the planned value from the effective electric power, for the adjustment power providing means performing demand or supply of electric power according to the planned value.

5. The adjustment power measuring device according to claim 1, further comprising:
an integration unit that calculates an adjustment power integrated value obtained by integrating the first adjustment power, which is measured by the measuring unit, in a predetermined unit period.

6. The adjustment power measuring device according to claim 5, wherein
the acquisition unit further acquires second adjustment power, which is adjustment power that responds to supply and demand variation having a cycle shorter than that of the first adjustment power and which is based on a frequency at the connection point and the effective electric power exchanged at the connection point, and
the integration unit calculates the adjustment power integrated value based on the first adjustment power measured by the measuring unit and the second adjustment power acquired by the acquisition unit.

7. The adjustment power measuring device according to claim 1, further comprising:
a second calculation unit that calculates electric power demand or electric power supply of the first power transmission and distribution network based on the effective electric power of a plurality of adjustment power providing means acquired by the acquisition unit, wherein
the first calculation unit calculates the electric power demand or the electric power supply of the entire electric power system by calculating a total of the electric power demand or the electric power supply of the first power transmission and distribution network, which is calculated by the second calculation unit, and electric power demand or electric power supply of a second power transmission and distribution network, which is acquired from an adjustment power measuring device of a system operator who manages the second power transmission and distribution network included in the electric power system.

8. The adjustment power measuring device according to claim 1, wherein
the acquisition unit further acquires a frequency at the connection point, and
the first calculation unit calculates the electric power demand or the electric power supply of the entire electric power system based on the frequency and a reference value of a frequency set in the first power transmission and distribution network.

9. The adjustment power measuring device according to claim 5, wherein
the acquisition unit further acquires a frequency at the connection point,
the first calculation unit calculates a total value of short-cycle and long-cycle electric power demand or a total value of short-cycle and long-cycle electric power supply of the entire electric power system, based on the frequency and a reference value of a frequency set in the first power transmission and distribution network,
the measuring unit measures adjustment power corresponding to a single or a plurality of classifications in accordance with a speed of response of the electric power demand or the electric power supply, based on the total value of the electric power demand or the total value of the electric power supply, and
the integration unit calculates the adjustment power integrated value for each of the single or the plurality of classifications.

10. The adjustment power measuring device according to claim 9, wherein
the first calculation unit calculates a total value of the long-cycle electric power demand or a total value of the short-cycle electric power supply by further adding effective electric power generated by inertia of a rotating body included in the adjustment power providing means.

11. The adjustment power measuring device according to claim 10, wherein
the first calculation unit calculates the effective electric power generated by the inertia of the rotating body based on a parameter indicating a total sum of inertia of the electric power system acquired from an external server.

12. The adjustment power measuring device according to claim 9, wherein
the first calculation unit calculates the total value of the short-cycle and the long-cycle electric power demand or the total value of the short-cycle and the long-cycle electric power supply of the entire electric power system by further using a first transfer function indicating a weight of the frequency and a second transfer function indicating a weight of the reference value of the frequency.

13. An adjustment power measuring system that measures adjustment power of an electric power supply and demand balance provided to a first power transmission and distribution network that is a management target among a plurality of power transmission and distribution networks included in an electric power system, the adjustment power measuring system comprising:
an acquisition unit that acquires effective electric power exchanged at a connection point with adjustment power providing means capable of providing adjustment power to the first power transmission and distribution network;
a first calculation unit that calculates electric power demand or electric power supply of an entire electric power system including the first power transmission and distribution network; and
a measuring unit that measures first adjustment power provided to the first power transmission and distribution network by the adjustment power providing means, based on the effective electric power and the electric power demand or the electric power supply of the electric power system.

14. The adjustment power measuring system according to claim 13, wherein
the acquisition unit further acquires a frequency at the connection point, and
the measuring unit includes a first measuring unit that measures the first adjustment power and a second measuring unit that measures second adjustment power responding to supply and demand variation having a cycle shorter than that of the first adjustment power based on the effective electric power and the frequency.

15. The adjustment power measuring system according to claim 13, wherein
the acquisition unit further acquires a frequency at the connection point,
the first calculation unit calculates a total value of short-cycle and long-cycle electric power demand or a total value of short-cycle and long-cycle electric power supply of the entire electric power system, based on the frequency and a reference value of a frequency set in the first power transmission and distribution network, and
the measuring unit measures adjustment power corresponding to a single or a plurality of classifications in accordance with a speed of response of the electric power demand or the electric power supply, based on the total value of the electric power demand or the total value of the electric power supply.

16. The adjustment power measuring system according to claim 15, further comprising:
a representative frequency determination unit that inputs a frequency of a connection point serving as a sample point among a plurality of the connection points and outputs a representative frequency of an area including the sample point, wherein
the acquisition unit acquires the representative frequency as the frequency at the connection point.

17. An adjustment power measuring method of measuring adjustment power of an electric power supply and demand balance provided to a first power transmission and distribution network that is a management target among a plurality of power transmission and distribution networks included in an electric power system, the adjustment power measuring method comprising:
a step of acquiring effective electric power exchanged at a connection point with adjustment power providing means capable of providing adjustment power to the first power transmission and distribution network;
a step of calculating electric power demand or electric power supply of an entire electric power system including the first power transmission and distribution network; and
a step of measuring first adjustment power provided to the first power transmission and distribution network by the adjustment power providing means, based on the effective electric power and the electric power demand or the electric power supply of the electric power system.

18. A program for causing a computer of an adjustment power measuring device that measures adjustment power of an electric power supply and demand balance provided to a first power transmission and distribution network that is a management target among a plurality of power transmission and distribution networks included in an electric power system, to execute:
a step of acquiring effective electric power exchanged at a connection point with adjustment power providing means capable of providing adjustment power to the first power transmission and distribution network;
a step of calculating electric power demand or electric power supply of an entire electric power system including the first power transmission and distribution network; and
a step of measuring first adjustment power provided to the first power transmission and distribution network by the adjustment power providing means, based on the effective electric power and the electric power demand or the electric power supply of the electric power system.
